(19) United States
(12) Patent Application Publication
(10) Pub. No.: US 2014/0326186 A1
(43) Pub. Date: Nov. 6, 2014

(54) METAL-ORGANIC VAPOR PHASE EPITAXY SYSTEM AND PROCESS

(71) Applicant: Veeco Instruments, Inc., Plainview, NY (US)

(72) Inventors: Ajit Paranjpe, Basking Ridge, NJ (US); Alexander Gurary, Bridgewater, NJ (US); William Quinn, Whitehousestation, NJ (US)

(21) Appl. No.: 14/332,583

(22) Filed: Jul. 16, 2014

Related U.S. Application Data
(62) Division of application No. 13/441,531, filed on Apr. 6, 2012.
(60) Provisional application No. 61/472,925, filed on Apr. 7, 2011.

(51) Int. Cl. C30B 25/14; C30B 25/12

(52) U.S. Cl. CPC C30B 25/14; C30B 25/12
USPC 118/728

(57) ABSTRACT

A VPE reactor is improved by providing temperature control to within 0.5° C., and greater process gas uniformity via novel reactor shaping, unique wafer motion structures, improvements in thermal control systems, improvements in gas flow structures, improved methods for application of gas and temperature, and improved control systems for detecting and reducing process variation.

### RELATED APPLICATIONS

This application claims the benefit of the filing date of U.S. patent application Ser. No. 13/441,531, filed Apr. 6, 2012, which claims priority to U.S. Provisional Patent Application Ser. No. 61/472,925, filed Apr. 7, 2011, the disclosure and contents of which are hereby incorporated herein by reference.

### FIELD OF THE INVENTION

The present invention relates to metal-organic chemical vapor phase deposition, such as used in the manufacture of optoelectronic devices such as light-emitting diodes, laser diodes, photovoltaic devices, and other electronic devices such as Schottky barrier diodes and High Mobility Electron Mobility Transistors (HEMT).

### BACKGROUND OF THE INVENTION

Chemical vapor deposition (CVD) involves directing one or more gases containing reactive chemical species (precursors) onto a surface of a substrate so that their reaction forms a deposit on the surface. Vapor phase epitaxy (VPE) is a CVD process in which the substrate is a monocrystalline material, and the deposit grows as a single crystal. In VPE, the deposited layer takes periodic reference from the substrate crystal, and is referred to as an epitaxially grown layer. Metal-organic vapor phase epitaxy (MOVPE) is a VPE process that grows layers of compound semiconductor material. Alternative names for MOVPE used in the art include organo-metallic vapor phase epitaxy (OMVPE), metal-organic chemical vapor deposition (MOCVD), and organo-metallic chemical vapor deposition (OMCVD).

MOVPE is a non-equilibrium growth technique that relies on vapor transport of Group III alkyl and Group V hydride precursors to a heated substrate. The chemical species are provided by a combination of gases, including one or more metal organic compounds such as alkyls of gallium, indium, and aluminum, and one or more of the hydrides, such as NH₃, AsH₃, PH₃ and hydrides of antimony to form a “III-V” compound of the general formula InₓGa_{y}Al_{z}N_{A}As_{B}P_{C}Sb_{D} where X+Y+Z=approximately 1, and A+B+C+D=approximately 1, and each of X, Y, Z, A, B, C, and D can be between 0 and 1. In some instances, bismuth or boron may be used in place of some or all of the other Group III metals. Epitaxial growth of semiconductor compounds such as, for example, GaAs, GaN, GaAIAs, InGaAsSb, InP, ZnSe, ZnTe, HgCdTe, InAsSbP, InGaN, AlGaN, SiGe, SiC, ZnO and InGaAlP, and the like, can be achieved by MOVPE.

In MOVPE, precursor gases and other optionally additive species, or “dopants,” are supplied to the MOVPE reaction chamber where they react to form epitaxial layers on a heated substrate. Typically, the gases are fed into the reactor at a relatively low temperature, as for example, about 50° C. or below. As the gases reach the heated substrate, their temperature, and hence their available energy for reaction, increases.

Metal-organic epitaxial layers formed by MOVPE are useful for devices such as light-emitting diodes (LEDs), laser diodes, photovoltaics (PVs), and other electronic devices such as Schottky barrier diodes and High Mobility Electron Mobility Transistors (HEMT). These devices are formed by multi-layer epitaxial structures, and require tightly controlled layer thicknesses and compositions. As one example, in formation of blue LEDs and diode lasers, a multiple quantum well (MQW) structure can be formed by depositing layers of III-V semiconductor with different proportions of Ga and In. Each layer may be on the order of tens of Angstroms thick, i.e., a few atomic layers. For high device yield for such applications, the MOVPE process must grow layers that are essentially uniform in thickness and composition across a wide area of a substrate.

III-V semiconductors can also be grown using a hydride or a halide precursor gas process. In one halide vapor phase epitaxy (HVPE) process, Group III nitrides (e.g., GaN, AIN) are formed by reacting hot gaseous metal chlorides (e.g., GaCl or AlCl) with ammonia gas (NH₃). The metal chlorides are generated by passing hot HCl gas over the hot Group III metals. One feature of HVPE is that it can have a very high growth rate, up to 100 μm per hour, roughly ten times faster than MOVPE for some state-of-the-art processes. Another feature of HVPE is that it can be used to deposit relatively high quality films because films are grown in a carbon free environment and because the hot HCl gas provides a self-cleaning effect.

In both MOVPE and HVPE processes, the substrate is maintained at an elevated temperature within a reaction chamber. The precursor gases are typically mixed with inert carrier gases and are then directed into the reaction chamber. Typically, the gases are at a relatively low temperature when they are introduced into the reaction chamber. As the gases reach the hot substrate, their temperature, and hence their available energy for reaction, increases. Formation of the epitaxial layer occurs by final pyrolysis and subsequent chemical reaction of the constituent chemicals at the substrate surface. Crystals are formed by a chemical reaction and not by physical deposition processes. Growth occurs in the gas phase at moderate pressures. Consequently VPE is a desirable growth technique for thermodynamically metastable alloys.

In typical MOVPE processes, precursor gases are directed at the substrate or substrates in such a way that they react close to the substrate surface. This is done to maximize the epitaxial growth of the compound semiconductor layers, minimize gas phase reaction, and reduce the occurrence of spurious deposition on other surfaces. Typically, a gas mixture that contains the precursor alkyls, hydrides, carrier gases, and dopants, is caused to flow, as uniformly as possible, across the substrate by an array of gas injectors, leading to surface reaction. As the component atoms from the reacting precursors arrange themselves on the surface of the substrate, they settle onto low free energy positions such as lattice vacancies on its exposed crystal face.

The substrates used in MOVPE are often so-called “non-native” substrates, i.e., substrates of a different material than the epitaxially grown layers. Non-native substrates are used because native (i.e.; gallium-nitride and aluminum-nitride) substrates are currently unavailable in the quantities, size, and price range needed for economical large-scale manufacturing. Typical non-native substrates are made from silicon carbide (SiC) or aluminumoxide (sapphire). Virtually all LEDs made today are made on these types of substrates.

As noted above, epitaxially grown layers take periodic reference from the underlying substrate. Because of this, if the crystalline dimension of the substrate differs from that of the growing film, internal strain, often quite large, is generated at this interface. This situation referred to as “heteroepitaxy.” Heteroepitaxial strain results in wafer bending and bowing during MOVPE growth, since the growing crystal layer must be strained by tension or compression to match the crystal dimension of the substrate at the film-substrate interface. The accumulation of this strain is partially relieved by periodic lattice dislocations in the growing film, and can cause a monocrystalline film to be riddled with dislocation defect densities of 10⁸-10⁹/cm². These defects can severely degrade the quality of optoelectronic devices, and in severe cases can manifest themselves as extended slip planes or macroscopic cracks degrading device yield.

To ameliorate lattice dislocations caused by heteroepitaxy, a thin intermediate or “buffer” layer is sometimes deposited onto a substrate to moderate the interface and absorb some of the strain and localize the defects to at the buffer layer, thereby reducing the density of defects. Such buffer layers may be of the same material as the film or the substrate, but deposited under conditions that lead to low density, or they may be films of material with crystal lattice dimensions intermediate between the substrate and the desired top film, or they may be combinations of these types of films.

In some cases, buffer layers may comprise vertical fibrous crystal structures whose tops form epitaxial nucleation sites for the growing film, which may merge laterally during growth in a process called epitaxial lateral overgrowth (ELO) while residual strain is absorbed by expansion or contraction of the voids between the fibers. Such buffer layers may be advantageously deposited by sputtering, and because of the very small size of each nucleation site, may be made from materials with a wider range of crystal lattice dimensions. In one embodiment of the present invention, a sputter process module is used to deposit such a buffer layer prior to the deposition of MOVPE GaN. One such example is highly oriented PVD AIN that has been deposited at elevated temperatures that exhibits these characteristics and provides a template for direct two dimensional epitaxial growth of GaN

The strain induced by heteroepitaxy on non-native substrates poses a significant challenge for manufacturers of production MOVPE equipment, because the strain bows the wafer that forms the substrate, leading to temperature variations which lead to uneven growth rates between and within wafers. Variations in growth rate generate variations in the operating wavelengths of the optoelectronic devices—in the case of LEDs, it leads to variation in color, brightness, and electrical performance. Such variations result in losses, since the finished LEDs are sorted, or “binned,” according to color, brightness, and electrical performance. Excessive bow could result in film cracking or substrate chipping/cracking all of which reduce overall production yield. Residual stress/strain affects the electronic properties of the epitaxial stack for LEDs such as the brightness, efficiency loss at high injection currents (droop), and color shift at high injection currents.

Beyond heteroepitaxial growth, another source of wafer bowing and nonuniformity is thermal mismatch. The MOVPE process is performed at high substrate temperatures, typically in the range of 700-1400° C. Non-native substrates, such as sapphire and SiC, have a coefficient of thermal expansion (CTE) that differs from that of III-V compound semiconductors such as gallium-nitride and its various alloys. These “Ill-nitrides” form the basis for blue LED quantum well structures, currently among the most important epitaxial film structures grown by MOVPE. As a SiC or sapphire substrate is cooled after undergoing an MOVPE deposition process, it contracts a different rate than the III-V epitaxial film grown on it. This difference leads to wafer bowing and sometimes film and substrate cracking. Hence, this problem is referred to as “thermal mismatch”. Thermal mismatch-induced bowing may be addressed by using thicker substrates, but this is a solution that increases the back-end manufacturing expenses of dicing, grinding, and packaging.

### SUMMARY OF THE INVENTION

The present invention recognizes and addresses a number of aspects of MOVPE and HVPE to improve the uniformity of growth across the substrate, and constrain costs.

The overall objective is to develop high-volume epitaxial growth systems that provide reduce HB-LED per-device cost for epitaxial growth, with the ultimate goal of a reduction to a cost target of $2/klm compared to prior art systems. Epitaxial growth performance improvements have multiplying effects on downstream cost reductions of subsequent LED processes. The primary technology goals to be met include a 100% improvement in epitaxial yield, from 45% to over 90% for a 2 nanometer (±1 nm) wavelength bin. This goal requires improvements in material quality, process uniformity and repeatability to reduce brightness and wavelength yield losses.

These objectives are met by providing temperature control to within 0.5° C., thickness uniformity within 1%, indium composition control within the InGaN film to within 0.2 atomic percent, and novel reactor designs or improvements to existing reactor designs for improved efficiency and material quality. In addition, improvements in equipment efficiency, process recovery time, operator costs, uptime, and consumption of gases, utilities, spares, and other consumables contribute significantly to the cost reduction of epitaxial growth.

In one aspect, a dynamic thermal model of the wafer and wafer carrier system is used to accurately predict heat input effects on the wafer. Using the model, heat input to the wafer carrier may be adjusted to speed the ramp-up to a setpoint temperature without overshoot or oscillation, while maintaining wafer temperature uniformity.

In a further aspect, the present invention addresses a source of nonuniformity known as the “boundary layer” effect. Specifically, as the gas mixture flows across the substrate and crystal growth occurs, precursors are consumed and thus depleted from the mixture, and gaseous reaction byproducts accumulate in a “boundary layer,” which grows thicker as a function of flow length along the plane of the substrate. The boundary layer is depleted of precursor content and enriched in reaction products, and is thicker, the further it flows across the substrate. The variation in thickness of the boundary layer, if not addressed, increases the difficulty of maintaining uniform growth conditions across the substrate, and may result in non-uniform thickness and composition.

The present invention addresses features a reactor including a chamber and one substrate or one or more substrate carriers mounted for movement within the chamber, such as for rotational movement about an axis. The substrate carriers are adapted to hold one or more substrates, most preferably so that surfaces of the substrates to be treated lie substantially perpendicular to the axis. The reactor according to this aspect of the invention desirably includes a gas stream generator arranged to deliver one or more gas streams within the chamber directed toward the substrate carrier at a substantially uniform velocity. Process gas mixtures flow radially inward from injectors on the reactor wall, traveling a relatively short distance to a central heated exhaust tube located coaxially within the cylindrical reactor vessel. Additionally, a processing reactor for vapor phase epitaxy of a substrate is also provided where the reactor features a chamber comprising a substrate support, a gas flow injector for providing processing gas flow to a surface of the substrate; and a gas exhaust peripherally located relative to the substrate support to exhaust processing gas after exposure to the substrate, the chamber having a profile that decreases in distance from the substrate support adjacent to a periphery of the substrate support as compared to a central area of the substrate.

Beneficial features of the inward radial gas flow of the current invention include the natural tendency of this flow to compensate for precursor depletion. As the gas mixture flows toward the central exhaust, its precursor content is depleted as reaction area is decreased, so the need for compensation by additional gas injection is reduced or eliminated. Also, as the gas mixture flows radially inward, it is compressed and its velocity increases. This compresses the boundary layer as velocity and the mean free path are increased, reducing or eliminating another effect that normally requires compensation.

In another aspect, the invention improves the utilization of gas, precursor and dopant, and thus reduces the cost of a MOVPE process. Gas, precursor and dopant consumption is typically a significant fraction of the total cost for epitaxial growth and thus high usage efficiency (i.e. % of gas that results in a useful deposition on the wafer) is desirable. Another source of expense is the handling of unreacted gases, which accumulate in the system exhaust, downstream particle filters and other abatement systems, which require preventative maintenance on a relatively frequent schedule.

In accordance with this aspect of the invention, precursor gases are introduced with spatial and/or temporal separation, by periodically passing substrates through adjacent isolated gas injection zones, enabling the process to be continuous, i.e., without necessity for purge and refill steps in any one region. The current invention satisfies the requirements for temporal separation in ALE, and if used with MOVPE, it satisfies the requirement for spatial separation of precursors and solves the issues of “reverse jetting,” “dead flow zones,” and “parasitic deposition.”

This aspect of the invention offers several advantages. In MOVPE, precursor mixing is reduced, and in ALE, valves and automation sequences are reduced or eliminated, as is the time limitation associated with filling and purging cycles in a single-zone process. In addition, the usage efficiency of the gases can be increased significantly (by orders of magnitude) over prior art systems since the unused/unreacted gas is not pumped out between cycles and thus has a substantially longer (by 10 times to 1000 times) residence time within each chamber. The lower gas flow rates also reduce the need for exhaust management and abatement prolonging preventative maintenance intervals. Using a dedicated exhaust for each reactant stream significantly reduces exhaust clogging by-product formation downstream of the reactor.

In a further aspect, the invention features a chamber that improves the uniformity of gas pressure in an MOVPE process, and thereby improves the uniformity of deposition in the chamber. Specifically, gas flow is compressed near the edge of the wafer carrier by modification of the chamber shape. The compression of the gas flow compensates for the drop in pressure caused by gas flow velocity changing as it drops off the edge of the wafer carrier into the lower portion of the MOVPE chamber. This reduces edge-to-center pressure gradient, thus reducing process variations caused by variation in pressure.

In a further aspect, that is especially well-suited to use with larger wafers, the wafer pocket used to hold wafers for processing comprises a flexible diaphragm. A heat conductive gas at the back of the diaphragm is maintained under regulated pressure control, so that the diaphragm may be shaped in a manner that adapts to a changing shape, for example, bowed or cupped, to match the shape of the wafer as it changes through the MOVPE process. This allows a smaller gap to be maintained between the pocket and the wafer, enabling better heat transfer and uniformity. It also allows the heat uniformity to be maximized during all stages of the MOVPE growth process, not just on step. Deflection of the diaphragm is monitored optically from behind or is pre-characterized as a function of, among other things, operating conditions of the chamber, pressure difference between the chamber and the cavity adjacent to the rear face of the diaphragm behind the pocket, measured deflection of the wafer and/or the diaphragm, and/or predicted process induced wafer deflection and is adjusted to match the process induced wafer deflection measured from above.

In a further aspect, the invention features the individual control of multiple wafer temperatures within a single wafer carrier. A conductive gas, for instance helium, is individually introduced on the back side of each wafer to conduct heat between the wafer carrier and the wafer. Heat conduction may thereby be individually controlled at each wafer pocket on the wafer carrier, by controlling the flow rate and pressure of conductive gas flow at each pocket. This allows adjustments to be made so that variations in the average processing temperature of individual wafers, and thus the variation in average wavelength of quantum well structures between different wafers, can be reduced.

In conjunction with this aspect, the heat conducting gas at the back side of each wafer is induced to rotate within the pocket. In one embodiment of the present invention, the gas is directed to flow across the wafer's back surface while inducing rotation, so that the difference in tangential gas velocity between the back and front sides of the wafer may be used to induce a Bernoulli Effect, essentially lowering the pressure on the back side and acting to retain the wafer within the pocket, on a cushion of heat-conducting gas. This rotation, in addition to the wafer carrier rotation, generates a compound movement known as “planetary motion” that helps to improve process uniformity within each wafer. Alternate forms of planetary motion such as a gear drive accomplish a similar purpose.

Complimentary to the individual backside gas heat coupling adjustments, a wafer or wafers within the wafer carrier may be individually heated by flash lamp radiation. In this embodiment, flash lamps or alternate forms of focused high repetition rate radiation such as high power blue LED lamps positioned above the wafer carrier may be triggered so that their radiation is absorbed by a selected wafer or wafers in order to add heat energy to that wafer or wafers. This may correct both within wafer and wafer-to-wafer temperature non-uniformity. Alternatively, the flash lamps may be used exclusively rather than in combination with gas flow adjustment or planetary motion. A method of performing vapor phase epitaxy also features placing wafers to be processed in a carrier in a chamber, each wafer having a front face exposed to the chamber and a rear face, performing steps of a vapor phase epitaxy process upon the wafers; and during the vapor phase epitaxy process, exposing a front face of at least one wafer to lamp radiation to provide a controlled heat transfer thereto. The lamp radiation can be provided by, for example, a flash lamp or LED radiation. The lamp radiation is applied nonuniformty to the front face of a wafer to adjust for temperature nonuniformity. During the vapor phase epitaxy process, a heat conductive gas can be supplied to a cavity adjacent to the back face of each wafer. The gas can be supplied at different pressures behind each wafer and at controllably selected pressures, based upon a desired heat transfer from or to each wafer.

In a further aspect, a hybrid heater design, comprised of separate radiant and resistive heating elements, allows the heat input to the wafer carrier to be varied at different radial positions. Using supplemental annular rings of resistive heaters on the wafer carrier at radii corresponding to the inner and/or outer edges of the wafer pockets, each wafer may experience additional heat input near its edge. With wafer rotation, this additional input becomes an averaged peripheral heat input that may balance the influence of thermal blanketing. In the disclosed particular embodiment, this reduces temperature non-uniformity to less than 3° C. This is a range over which pocket shaping may be used to reduce the temperature variation even further. To reduce the burden on the zone heating, the surface of the carrier that is not covered by wafers may be covered by inserts that provide a similar ‘blanketing’ effect of the wafers. By eliminating sharp heat loss gradients across the carrier, the intrinsic temperature uniformity of the carrier is improved.

In a further aspect, combined gas flows are used on the surface of the wafer to improve uniformity. For example, additional flow directed downward from above, comprised of heated nitrogen gas. The downward flowing heated nitrogen gas is injected at a velocity that is linearly proportional to the distance from the central gas injector, with the desired result of compressing the boundary layer and improving process uniformity across the wafer carrier. In a second embodiment of the current invention, a FlowFlange-type or Uniform FlowFlange-type injector is combined with a central cross-flow injector to form a hybrid injector. In a third embodiment, the cross flow injector is positioned in an outboard peripheral relationship to the wafer carrier, so that its gas flow is directed radially inward toward a central heated exhaust port. An additional flow may be directed downward from above, comprised of heated nitrogen gas. In a fourth embodiment, a FlowFlange-type injector or Uniform Flow_Flange-type injector is combined with a peripheral cross-flow injector to form a hybrid injector, in which gas flow is directed radially inward toward a central heated exhaust port.

In another aspect, a single-wafer MOVPE reactor provides a linearly uniform flow of gases across the rotating wafer. This is accomplished by introducing the gases through a set of linear injectors along an inner side wall within the reactor. Various constructions of the gas flow injectors and exhausts in the single reactor are illustrated for embodiments of this aspect.

In a further aspect, the photoluminescence (PL) response of a wafer is mapped after multi-quantum well growth to detect process drift resulting in variations in the indium incorporation and thickness. PL mapping in incorporated into the MOVPE system, and any drift detected is correlated to known factors and responses. For instance, a uniform change in the PL over all wafers in an entire wafer carrier may indicate a drift toward higher or lower processing temperature. By identifying process drift resulting in variations in photoluminescence response of the wafer, adjustments can be made to one or more of processing gas flow, processing gas exposure time, processing temperature, process uniformity calibration and process duration calibration in response to identified variation in photoluminescence response.

In an additional aspect, a heated flange is implemented at the gas injection site, so that gases can be brought to a relatively high inlet temperature such as about 100° C. to about 250° C. when introduced into the chamber. Preferably, the walls of the chamber are maintained at a temperature within about 50° C. of the inlet temperature.

In a further aspect, the invention features a planetary wafer holder that permits compound substrate motion during MOVPE or any other type of wafer process, including CVD, PVD, or ion beam processes. A wafer carrier of the present invention has situated upon it one or more eccentrically positioned planets. There are gear teeth or other coupling means around each wafer holder. The wafer carrier, in the form a disc, is centrally supported on a rotatable spindle and hub assembly. Direct contact between the wafer carrier and the hub is through a supporting ring of bearings, so the wafer carrier is able to rotate independently of the hub. The hub has gear teeth around its perimeter that project into openings on the wafer carrier where the individual planets are retained, so that they mesh with the gear teeth on the periphery of each planet. The central hub is driven to rotate at any speed and in either directional sense, clockwise or counterclockwise. When the hub rotates, the gear mesh coupling to the planets causes the planets to individually rotate within their positions in the same rotational sense and at a speed initially proportional to the ratios of the circumferences of the hub and planets. However, the coupling between the hub and the wafer carrier is through the rolling friction transferred across the bearings, so that the rotation of planets is responsive to frictional balance and not constantly proportional to the ratios of circumferences of the hub and planets. Specifically, by accelerating and decelerating the hub about a constant average speed, the planets are induced to periodically reverse their direction of rotation while the wafer carrier continues to rotate with the same average velocity (in the same directional sense), providing a complex motion that improves averaging and evening of process performance across wafers.

In a further aspect, the present invention addresses nonuniformity resulting from wafer bowing either due to thermal mismatch or hereroepitaxy, by precision etching of thin trenches or “streets” over the substrates, into which cracking may be mostly confined, so that long-range strain is periodically relieved. The inventive technique embodies the use of precise KrF laser illumination to induce UV-activated etching by HCl/Cl₂ gas mixtures.

The above and other objects and advantages of the present invention shall be made apparent from the accompanying drawings and the description thereof.

### BRIEF DESCRIPTION OF THE DRAWINGS

The accompanying drawings, which are incorporated in and constitute a part of this specification, illustrate embodiments of the invention and, together with a general description of the invention given above, and the detailed description of the embodiments given below, serve to explain the principles of the invention.

FIG. 1 shows photoluminescence (PL) wavelength as a function of temperature and QW Well Thickness.

FIG. 2 is an illustration of typical wafer carrier temperature distribution and the “blanketing” effect of wafers on a carrier.

FIG. 3 is a chart of the black body radiance of a sapphire wafer.

FIG. 4 is a chart illustrating methods applied according to the present invention for yield and productivity gain and cost reduction.

FIG. 5A is a block diagram of a model-based temperature controller that incorporates an adaptive thermal model in accordance with principles of the present invention.

FIG. 5B is an architectural model of the block diagram of FIG. 5A.

FIG. 6A is a plan view of substrate carriers stacked within a MOVPE reactor.

FIG. 6B is a top view of the reactor in FIG. 6A (with top removed).

FIG. 6C is a plan view of a system similar to that shown in FIG. 6A.

FIG. 6D is a top view of the reactor in FIG. 6C (with top removed).

FIG. 7A illustrates a cyclic gas injector system having isolated gas injection zones.

FIG. 7B shows an example of one orientation of gas flow.

FIG. 7C shows another example of an orientation of gas flow.

FIG. 8A is a partial cross sectional view of a reactor.

FIG. 8B is top view schematic showing a general orientation of stack of azimuthally or axially segmented gas injectors.

FIG. 9 is a cross sectional view of a wafer carrier in accordance with an aspect of the present invention;

FIG. 10 illustrates wafer-to-wafer temperature variation based on varying helium flow.

FIG. 11 illustrates gas flow uniformity of a hybrid injector.

FIG. 12 is a cross-sectional view of a single-wafer reactor;

FIG. 13 is a cross section schematic view of an injector system for the single wafer reactor of FIG. 12.

FIGS. 14A and 14B illustrate approaches to reducing parasitic coating used in a single wafer reactor.

FIG. 15A is a plan view of a wafer carrier implementing an inertial drive planetary motion.

FIG. 15B is a perspective view of one of the wafer supports of FIG. 15A.

FIG. 16 illustrates an example of a combined embodiment incorporating various aspects of the invention described herein.

### DETAILED DESCRIPTION OF THE INVENTION

There are many categories that contribute to the cost of blue LED structures grown using MOCVD. The largest category is yield loss, and is caused by the non-uniform distribution of material, optical, or electrical properties across each wafer, between wafers in a single growth run, and between growth runs. Fixed costs are most strongly affected by throughput, capital cost, and equipment footprint. Ammonia and alkyl source consumption are functions of chamber and gas flow design, and are significant contributors to cost of ownership. Manufacturing efficiency, operational aspects of using the system, including maintenance schedules, idle time, calibration, and process qualification, is a small amount when compared to fixed costs and yield loss. Substrate cost involves the wafers used for LED growth; improvements in wafer quality and sizing. Changes in substrates can accelerate and enhance cost reductions.

An analysis of the key contributors to epitaxial growth cost reduction shows that the top five contributors (yield, quality, capital expenditure efficiency, process recovery time, and utilities) contribute to over 80% of the cost reduction target. Improving these top five contributors to yield loss, is therefore the primary technology development necessary to achieve epitaxial growth cost reduction in the short term. Aspects of the present invention pursue improvements in yield, material quality (to enable brightness improvements), capital expense efficiency, process recovery time, and gas and utility usage.

As discussed, yield loss is the most important parameter for MOCVD equipment cost of ownership. The major limiting factor for yield of LED chips is the relatively poor uniformity and reproducibility of the MOCVD process used for epitaxial growth of LEDs in the context of the stringent SSL wavelength binning demands of ±1 nm.

For typical GaN based LED structures, wavelength is the largest contributor to yield loss (this refers to either wavelength variation or incorrect wavelength centering). Wavelength variation has a number of sources. During growth, the wavelength within a wafer is not monotonic, but rather a distribution of wavelengths. High volume MOCVD systems process a number of wafers simultaneously, and each wafer may have a different average wavelength and a different wavelength distribution. Wavelength centering generally shows a small shift in wavelength from one run to the next. Non-uniformities due to gas flow, temperature, and reaction chemistry are the primary causes for wavelength variation and centering challenges.

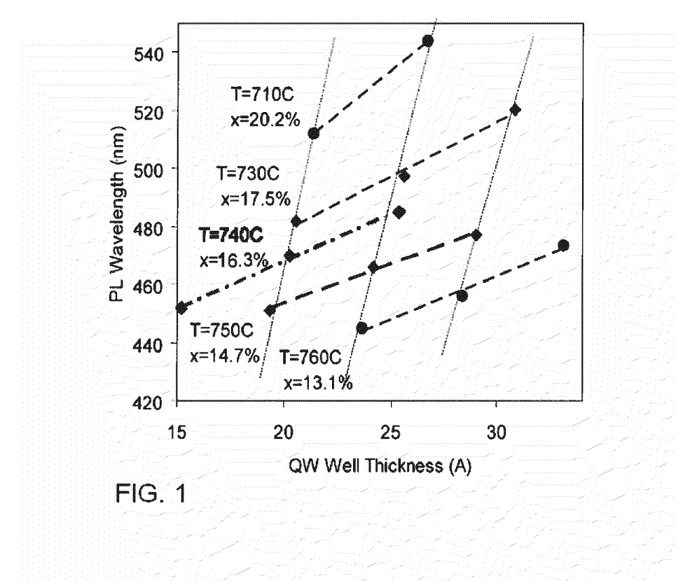

FIG. 1 illustrates the temperature, well thickness and composition control requirements for wavelength control. The wavelength dependence on growth temperature and InGaN layer thickness shows that temperature has a large effect on uniformity (within wafer, wafer to wafer, and run to run). Temperature and temperature uniformity must be controlled to several tenths of a degree during the epitaxial growth to achieve consistently high yield. Each degree change in temperature produces about a 2 nm change in wavelength for blue LEDs and about a 3 nm wavelength shift for green LEDs. FIG. 1 shows that, in general, the following relationships hold:

Δλ/ΔT≈1.8 nm/° C.

Δλ/Δx≈12 nm/% (x is % In)

Δλ/ΔtQW≈3 nm/A

Temperature uncertainty and non-uniformity arises from several causes. Large scale thermal uniformity is dictated by the bulk heating system and susceptor design and the uniformity of cooling governed by the surrounding gas and chamber design. Known epitaxial equipment allows for some control of these large scale thermal factors, however small scale thermal non-uniformities currently prevent high yields in a SSL wavelength bin (2 nm). These small scale thermal non-uniformities include:
radiance trapping or ‘blanketing’ effect of the transparent substrates,
continually varying substrate bow during growth which alters the surface temperature distribution of the wafer, and
uncertainty in surface temperature caused by the inability to directly measure the surface temperature of the substrate with sufficient accuracy.

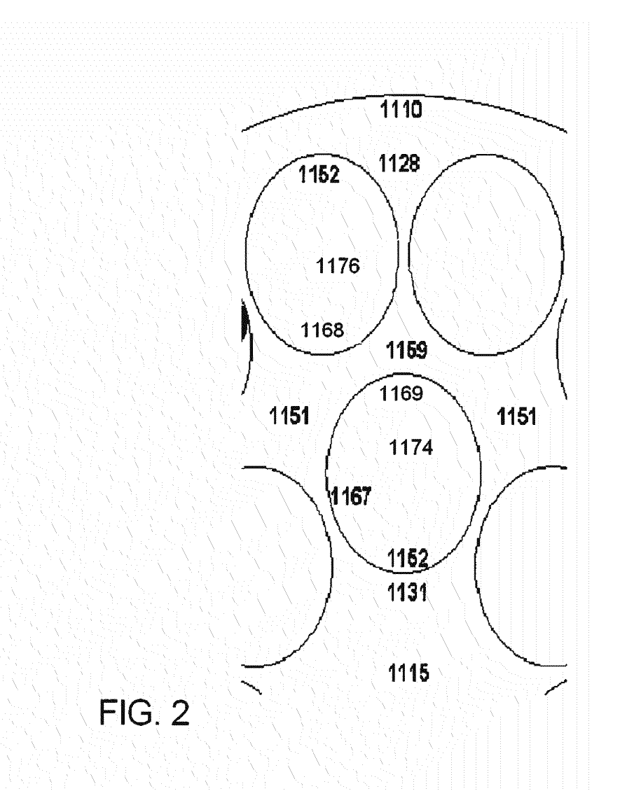

FIG. 2 shows an example of the ‘blanketing’ effect of sapphire wafers on an otherwise uniformly heated wafer platen (modeling based on a Veeco E300 reactor), showing there is a need for multi-point temperature measurement. Other issues include proximity induced thermal non-uniformity related to wafer temperature, gas temperature, and gas flow. Subtle differences in pocket temperature and gas temperature based on the proximity to neighboring wafers can result in leading/trailing edge effects. These differences and effects must be compensated for and/or corrected in order to achieve a >90% yield. Other components of variation include gas temperature variation, gas flow variation, and edge induced wafer temperature nonuniformity. Temperature correction is generally required for each source of non-uniformity quantified.

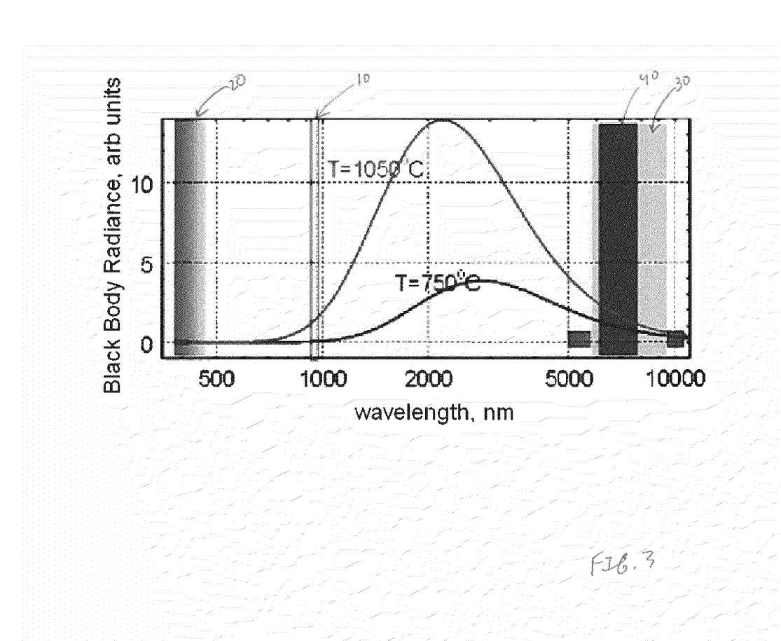

Countering the thermal effects outlined above requires multi-zone temperature measurement, multi-zone heater control, and most importantly pyrometers with high signal to noise (S/N ratios) in the emission wavelengths of a sapphire substrate at typical growth temperatures. As seen in FIG. 3, detection using conventional pyrometry 10 does not have the capability to directly measure the substrate temperature at these emission wavelengths, for example, hot GaN absorption band 20, sapphire absorption band 30, and NH₃ absorption 40, which is why advanced UV and mid-IR pyrometry is needed. Specifically, FIG. 3 shows that the black body radiance of a sapphire wafer at typical GaN growth temperature (1050° C.) and GaN/InGaN MQW growth temperature (750° C.) requires pyrometry sensitive at wavelengths above 2000 nm, twice those sensed by conventional pyrometry.

In summary, FIG. 4 illustrates the areas for improvements and solutions discussed in this application for achieving 4X epitaxial process cost reduction. This illustrates that concurrent advancements on multiple fronts are required to accomplish this cost reduction goal for solid state lighting. Each of these improvements are individually described below.

### Model-Based Temperature Control

Because MOVPE processes are carried out at high temperatures, much of the time consumed by MOVPE processes is involved in the heating of substrates and the stabilization of process temperature. This is a critical factor in LED manufacture, since even small deviations above or below temperature setpoint will result in unacceptable wavelength variation.

Traditionally, ramp and control of temperature has been accomplished using “Proportional-Integral-Derivative” (PID) techniques. Using PID control, temperature setpoint may be reached at a very high ramp rate, but this will result in a set of damped oscillations above and below the setpoint value. These oscillations can typically have enough amplitude to preclude processing until they have been damped to below about 0.5° C. Slower ramps result in less overshoot and undershoot, but obviously take longer. The time required to reach and stabilize substrate temperature is non-value-adding and reduces throughput.

In the current invention, a dynamic thermal model of the wafer and wafer carrier system has been developed to accurately predict heat input effects on the wafer. Using the model, heat input to the wafer carrier may be optimized to allow maximum ramp to setpoint temperature without overshoot or oscillation, while maintaining wafer temperature uniformity. Constant wafer temperature uniformity helps prevent unnecessary wafer bowing and possible wafer loss during the temperature ramp, during both heating and cooling ramps.

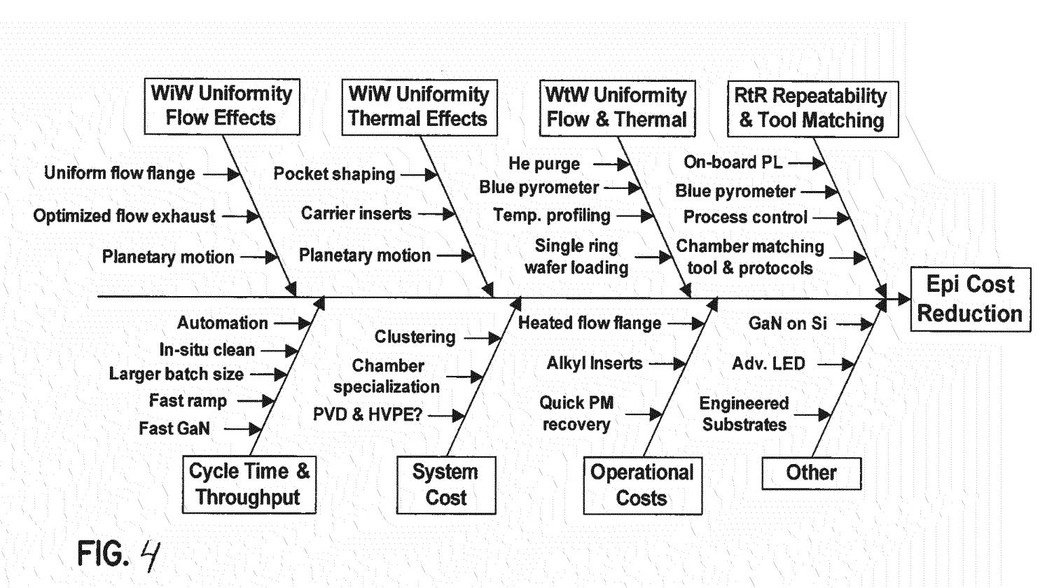

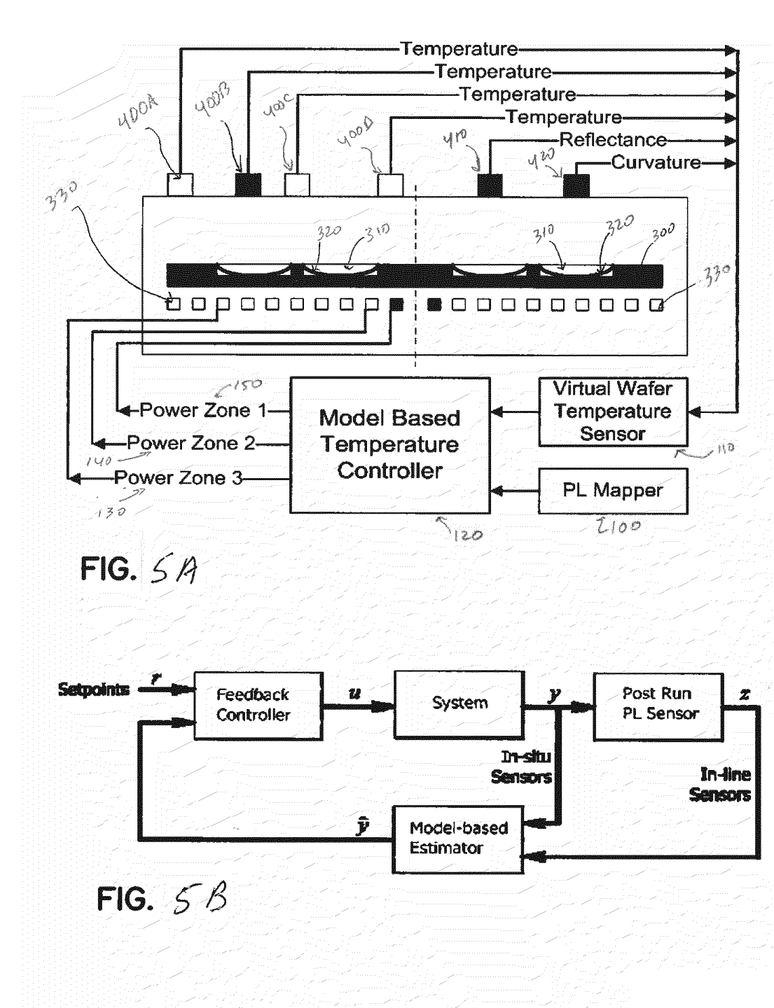

FIG. 5A illustrates a model-based feedback controller that can accomplish this improvement. The accuracy of this controller is directly proportional to the models used in the controller and the precision of data acquisition. The controller is designed to compensate for various error and drift sources that may occur within a run or from run to run.

As seen in FIG. 5A, a model-based temperature controller, discussed in detail below, incorporates an adaptive thermal model of the system and utilizes multiple inputs (temperature, reflectance, curvature, PL wavelength) to control each zone of the heating source while compensating for various errors and drift sources (emissivity, pyrometer, window coating). Temperature sensors 400A, 400B, 400C, and 400D, which can be typically a pyrometer, reflectance sensor (reflectometer) 410, and curvature sensor (e.g., deflectometer) 420 provide real time data to Virtual Wafer Temperature Sensor 110 while wafer carrier 300, which has wafers 320 situated in pockets 310, is rotated on a spindle (not shown) at various process temperatures (the varying temperatures being provided by heating elements 330). PL Mapper 100 constantly monitors various parameters within the reactor (not shown), such as reactor emissivity, pumping speed, precursor delivery, and the like. Model Based Temperature Controller 120 can correct for and minimize random PL wavelength drift and the data from PL Mapper 100 to the Model Based Temperature Controller 120 allows for more control for slower, longer term drift issues within the reactor so that high yields can be consistently achieved over an extended period of time.

FIG. 5B shows a general schematic architecture of the model-based temperature control includes a feedback controller, model-based estimator, in-situ sensors, and post-run in-line sensors.

Through the system described in FIGS. 5A and 5B, improvements in process time, stabilization and uniformity have been accomplished by model based temperature control according to the present invention. The time required to alter temperature between process steps is substantially quicker with model-based control than has been possible with PID control. The reason for this improvement is that when using a traditional PID system, the ramp up and ramp down behavior of a proportional-integral-derivative control not only exhibits oscillation, but nonuniformity across wafers (from inner to outer), as compared to the model-based temperature control according to the present invention, which accomplishes far greater uniformity of temperature control across the wafer carrier.

The model-based temperature control (MBTC) system of the present invention allows temperature stabilization in half the time required with conventional PID control, mainly due to the reduction of overshoot and oscillation. Wafer temperature non-uniformity during ramping is reduced by 3×. MBTC also provides for identical heater ramping for a uniform temperature profile across the entire wafer carrier, which becomes more important as reactors move towards high capacity carriers and wafers are positioned closed to the carrier edge. The time saved by MBTC translates into more than 10% improvement in system throughput, and capital efficiency.

### Stacked and Radial Inward Cross Flow MOVPE

Several productivity issues are inherent to MOVPE technology; the deposition rate is low, in the range of 2-5 μm per hour, and the process temperatures are high, requiring long heating and cooling periods before and after deposition. Because of these issues, an MOVPE process can take several hours to complete. In order to make MOVPE systems more productive, it is attractive to seek solutions that increase batch size without significantly increasing the process time.

MOVPE is not easily scaled to large batch sizes; the mixed streams of precursor gases are continuously depleted and diluted by reaction byproducts, limiting the extent to which a uniform process can be maintained across a large area. Additionally, precursor gas mixtures readily react on places other than the intended substrate due to “reverse jetting” and “dead flow zones,” and result in process-degrading “parasitic deposition.”

A further difficulty in MOVPE is the need for temperature uniformity. Variations of more than 0.5° C. lead to measurable variations in the wavelength response of quantum well structures in LEDs, leading to losses during binning.

Batch processing in MOVPE typically involves wafer carriers and broad area gas injection systems. Precursor consumption on the wafer carrier is a geometric function of radius, as the gases flow radially outward to exit at the periphery. Individual wafer temperatures are monitored, if possible, and adjustments are made to the heat input from the wafer carrier to maintain wafer temperatures as close as possible to the target value.

One of the challenges that arise in MOVPE involves the general outward radial flow of gas streams, passing over the wafer carrier to the exhaust. As the gas streams move outward, they expand, slow down, and become depleted of precursors even as the reaction area under the stream is increasing. This causes changes in the process environment. To compensate for this effect, many complex and ultimately expensive solutions have been proposed. These include carefully controlled additional gas injection, shaping of the ceiling above the substrates to compensate for depletion, and employing planetary motion that utilizes rotational averaging of a linearly varying deposition profile in the flow direction to provide a nominally uniform film on the substrate.

This level of complexity and process sensitivity is warranted for quantum well structures, which are built from stacks of thin layers. Variations in the quality and uniformity of the thin layers have significant impact on the value of the finished device, but a reduction in complexity and expense would have tremendous benefit for manufacturers.

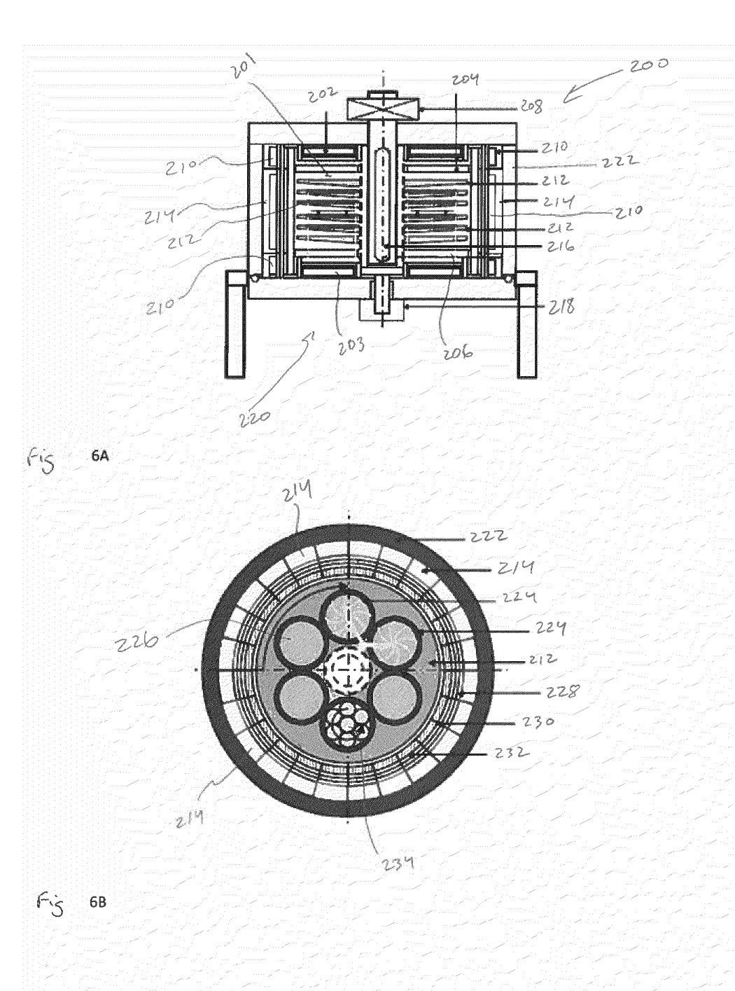

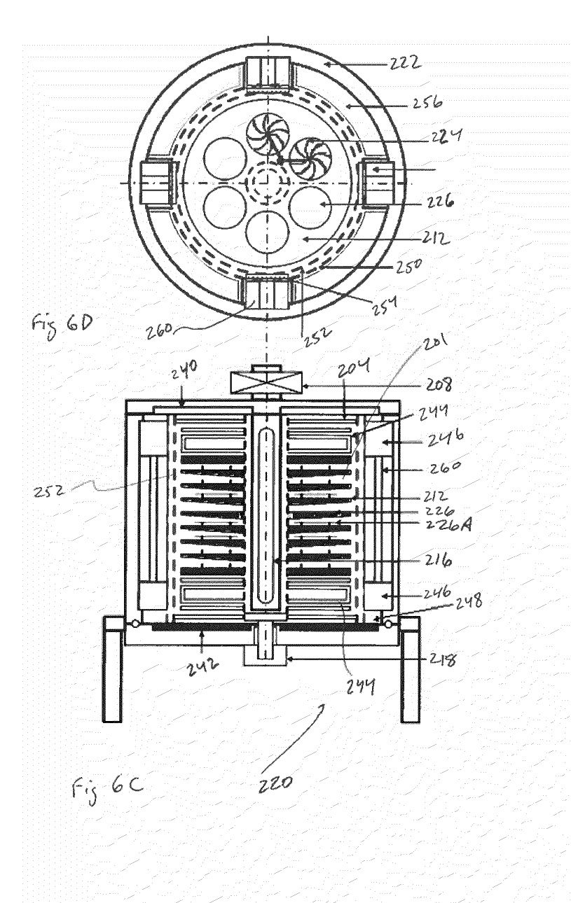

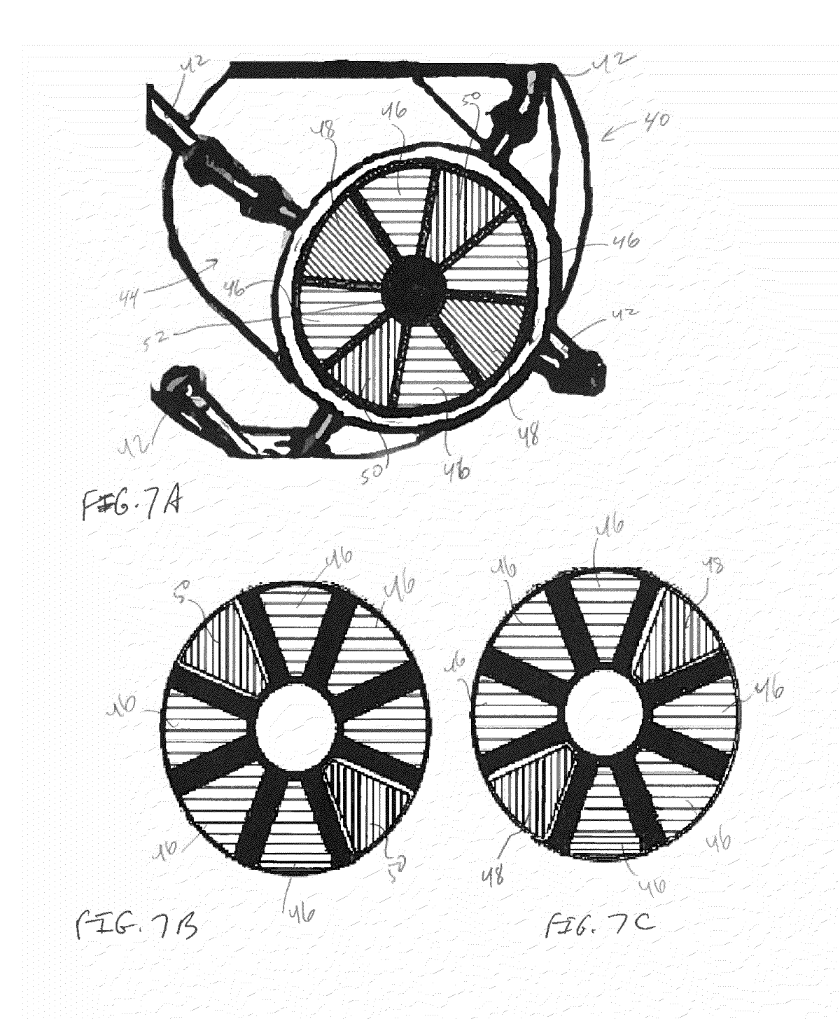

The present invention addresses these needs using a Stacked and Radial Inward (or Cyclonic) Cross Flow MOVPE reactor. FIG. 6A provides a cross sectional and FIG. 6B provides a plan view of a reactor 200, with a water cooled outer chamber body 222, according to this aspect of the invention, which includes a chamber 201 and one or more substrate carriers 212 mounted for movement within the chamber, most preferably for rotational movement about an axis. The substrate carriers 212 are adapted to hold one or more substrates 226, most preferably so that surfaces of the substrates 226 to be treated are arranged substantially perpendicular to the axis. The reactor 200 according to this aspect of the invention desirably includes a gas stream generator arranged to deliver one or more gas streams through temperature controlled showerheads 214 within the chamber 201 directed toward the substrate carrier 212 at a substantially uniform velocity.

In one embodiment of the current invention, a stack comprising one or more wafer carriers 212, or “susceptors,” is processed simultaneously within a single cylindrical reactor vessel. Substrates on wafer carrier 212 can be optionally rotated within the wafer carrier by gas bearing channels 224 or by planetary wafer carrier 234. Wafer carriers 212 rotate on a coaxially placed spindle (not shown) within the chamber 201, the spindle being controlled by mechanism 218. Process gas mixtures flow radially inward from heated injectors 210 on the reactor wall, traveling a relatively short distance through temperature controlled showerheads 214 to a central heated exhaust tube 216 located coaxially within the cylindrical reactor vessel. Gate valve 208 helps control gas exhaust from the central heated exhaust tube 216. The cylindrical reactor vessel is heated by induction heater 203 at the base, induction heater 202 at the top, and induction heater 210 (with ability to provide inert gas injection) at the wall so that its enclosed space, together with fixed top and bottom susceptors 204 and 206, respectively, and chamber liner 228 and perforated liner 232, together with barriers or baffles 230 between adjacent showerheads zones 214 forms an isothermal volume, or blackbody cavity, in which all components may come to thermal equilibrium with little or no temperature gradient. In this way, the current invention may perform a uniformly heated MOVPE process on a large number of wafer-carrying susceptors and requires gas mixture streams to travel a relatively short distance, i.e.; from the wall to the central axis of the cylindrical reactor vessel. Lower chamber 220 provides mechanisms for loading and unloading of wafer carriers 212. In some instances, a series of wafer carriers 212 can be contained within a cartridge or boat to allow for easy loading and unloading of many wafer carriers 212 in one operation. Lower chamber 220 also allows for multiple reactors 200 to be docked together.

Another embodiment is shown in FIGS. 6C and 6D, where the reference numbers used therein have the same meaning as those used in FIG. 6A and FIG. 6B. In the system shown in FIG. 6C, there is used instead a top and bottom multi-zone heater 240 and 242, respectively. The fixed top and bottom susceptors 204 and 206 from the system in FIG. 6A are replaced with fixed top and bottom evacuated quartz susceptors 244. Liners 228 and 232 and baffle 230 from the system in FIG. 6A are replaced with perforated quartz chamber liner 250 and perforated SiC coated graphite chamber liner 252. Reactive gases are introduced into chamber 201 through reactive gas injector zones 246, which pass through a 1 to 3 zone gas pre-heater prior to entering the chamber 201. Port 248 allows for inert gas injection around the liner 250. Multi-zone heater 256 allows for further temperature control of the chamber 201. Wafer 226 can sit within a pocket on susceptor 212 or rest on pins (wafer 226) on a susceptor 212.

In all embodiments of the invention, the substrate or substrates may rotate about their centers as the substrate carriers rotate, generating a compound, or “planetary,” motion to more evenly apply the growth process over the surface of each substrate.

Beneficial features of the inward radial gas flow of the current invention include the natural tendency of this flow to compensate for precursor depletion. As the gas mixture flows toward the central exhaust, its precursor content is depleted as reaction area is decreased, so the need for compensation by additional gas injection is reduced or eliminated. Also, as the gas mixture flows radially inward, it is compressed and its velocity increases. This compresses the boundary layer as velocity and the mean free path are increased, reducing or eliminating another effect that normally requires compensation.

The gas stream generator most preferably is arranged so that the one or more gas streams include a carrier gas and a reactant gas, and so that different portions of the one or more gas streams contain different concentrations of the reactant gas. Where the substrate carrier is mounted for rotational movement about an axis, the gas stream generator desirably is arranged to supply the one or more gas streams with different concentrations of the reactant from a heated wall of the reactor, at a radius from the axis that is equal to or larger than the outer radius of the wafer carriers. The gas stream directed inward toward the substrate or substrates passes over the outer portion of the substrate carrier near the periphery, and desirably includes a relatively large concentration of the reactant gas and a relatively small concentration of the carrier gas. As the gas stream flows inward in its cyclonic trajectory toward the axial exhaust port, the reactant component is consumed though its concentration above any element of the reaction surface stays roughly constant. This beneficial effect is a natural consequence of multiple radial gas streams converging, and is a major advantage of the present invention.

The gas stream generator may include a plurality of gas inlets communicating with the chamber at axially or radially different positions in the wall, so that each substrate carrier receives substantially the same flow in a time-averaged fashion, as well as one or more sources of a reactant gas connected to the inlets and one or more sources of a carrier gas connected to at least one of the inlets.

A further aspect of the invention includes methods of treating substrates. A method according to this aspect of the invention desirably includes rotating a substrate support about an axis while supporting one or more substrates to be treated on the support so that surfaces of the substrates lie substantially perpendicular to said axis. The method further includes introducing a reactant gas and a carrier gas into the chamber so that said gases flow within said chamber toward the surfaces in one or more streams having substantially uniform concentration at different radial distances from said axis.

The one or more gas streams are arranged so that different portions of the substrate surfaces at different radial distances from the axis receive substantially the same amount of said reactant gas per unit time per unit area.

The gas injection scheme can be combined with other known methods for uniform distribution of the reactant gas such as multi-zone showerhead to provide additional process flexibility. Preferred reactors and methods according to the foregoing aspects of the invention can provide uniform distribution of the reactant gas over the treatment surface of a substrate carrier, such as over the surface of a rotating disk substrate carrier, while avoiding turbulence caused by differing reactant gas velocities.

### Cyclic Gas Injector

Gas injector designers for MOVPE have struggled for many years with the issues of “reverse jetting,” “dead flow zones,” and “parasitic deposition.” These negative effects cause, or result from, precursor gases mixing and reacting on places other than the intended substrate. Gas injectors are therefore designed to provide spatial separation between precursor nozzles as well as non-reactive gas streams and sheath flows to help keep precursors separated until they reach the substrate. This results in high gas usage, low efficiency, and extremely complex and expensive gas injector systems.

In atomic-layer epitaxy (ALE), the precursors must be introduced at separate points in time, and the first precursor flushed from the reactor before the second is introduced. The first precursor leaves a residual adsorbed layer on the substrate, forming an atomic or compound molecular monolayer—a single layer of molecules. Reactions proceed at the monolayer-coated surface when a second precursor is introduced. This reaction is aided by two factors: the temperature of the reaction surface, which increases the energy available for reaction, and by the reduced energy requirement for dissociation and reaction when one component is adsorbed on a surface (thus reducing the number of degrees of freedom). In the prior art, this process is carried out in a single zone, requiring exposure of the substrate to one precursor, followed by the purging of un-adsorbed gas, followed by the introduction of the second precursor, then a second purge cycle, etc. This process results in slow deposition, though the thin films thus formed are almost perfectly conformal and uniform in thickness, and may be scaled to coat large substrate areas quite easily. Additionally, ALE processes have no gas-phase reaction or precursor mixing issues.

Some MOVPE precursors may be applied in the same way as ALE precursors, thereby avoiding the negative effects of gas-phase reaction and precursor mixing, but this would similarly result in very slow deposition rates. A solution that increases the efficiency and deposition rate of ALE growth may therefore be of great benefit to MOVPE through the elimination of gas-phase reaction and precursor mixing.

The present invention provides a gas injector system that solves the issue of precursor spatial separation without reducing the deposition rate, preserving separation but allows faster deposition.

In the current invention, precursor gases are introduced with spatial and/or temporal separation by periodically passing substrates through adjacent isolated gas injection zones, enabling the process to be continuous, i.e.; without necessity for purge and refill steps in any one region. This invention satisfies the requirements for temporal separation in ALE, and if used with MOVPE, it satisfies the requirement for spatial separation of precursors and solves the issues of “reverse jetting,” “dead flow zones,” and “parasitic deposition.”

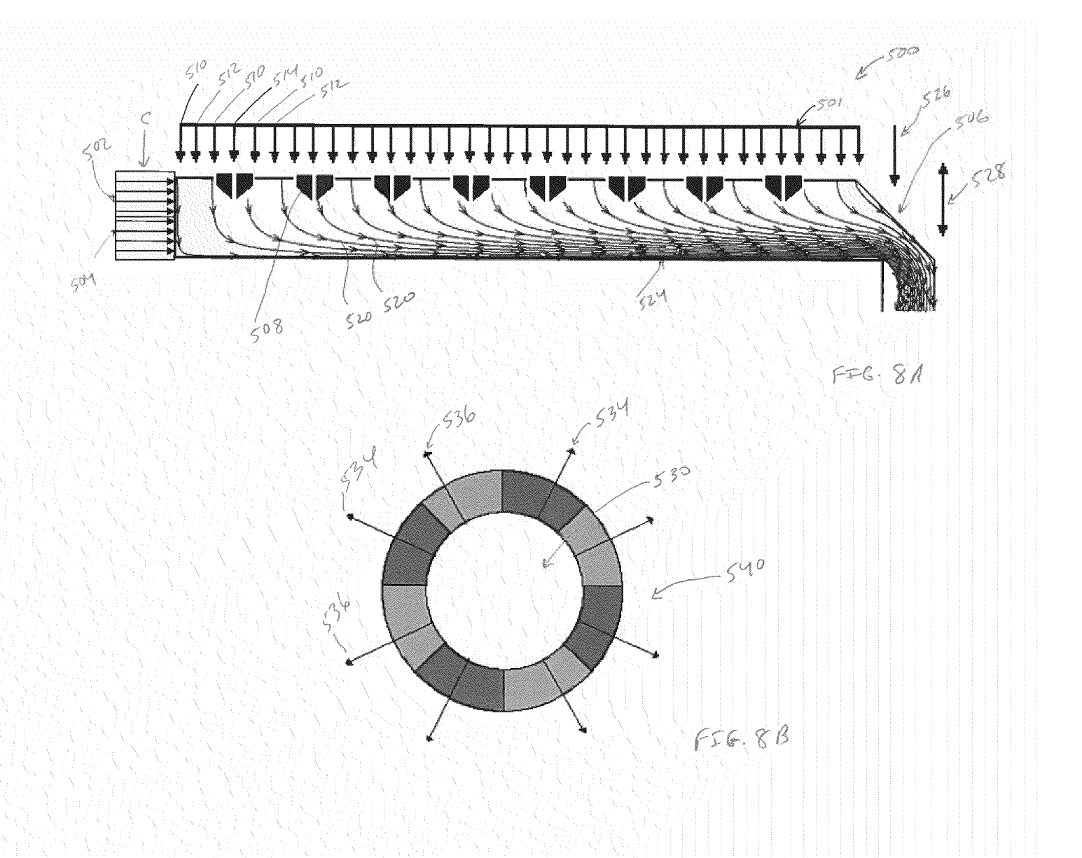

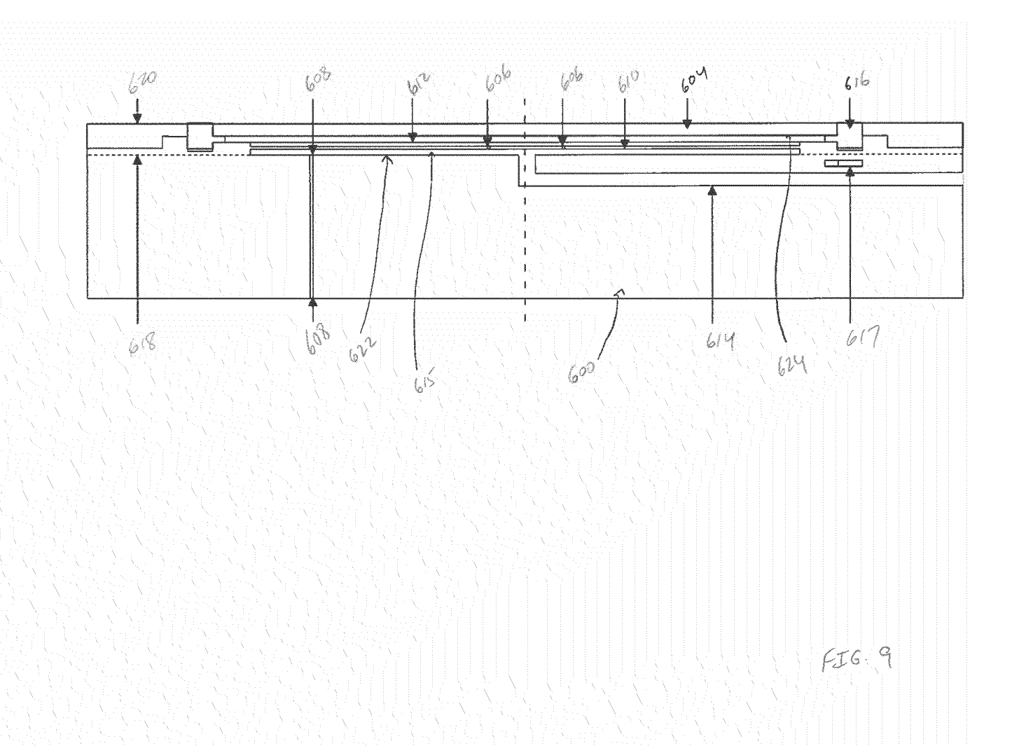

As illustrated in FIGS. 7A, 7B, and 7C, the current invention uses a circular array of isolated gas injection zones, each one defined by a ceiling and a peripheral wall. Each zone contains gas injectors and delivers a precursor gas or a carrier gas or combinations of precursor and carrier gases. A rotating wafer carrier is positioned coaxially with its surface parallel in relation to the circular array, close enough so that only a low-conductance gap remains between the wafer and the peripheral walls of each zone within the array. Gas flow into or out of each zone is hindered by virtue of the small low-conductance gap between the wafer carrier and the peripheral wall of each zone. Substrates continuously pass below each zone in turn as the wafer carrier rotates, alternately entering and exiting each zone and repeating the cycle.

In FIG. 7A, gas injector system 40 has a wall 44 which contains various gas handling, temperature, and control components typically found in CVD type systems. Gas inlets 42 deliver the Group III, Group V, and inert gases to the system. Inert gas (for example, N₂, H₂, and mixtures thereof) enters through zone 46. These gases separate alkyl zone 50 from hydride zone 48. The inert gas in zone 46 can also be used during GaN etching processes. In use, the gases entering through zone 46 enter at a pressure P3.

Hydride gases (for example, NH₃, H₂, and mixtures thereof plus an inert gas, for example, N₂) enter through zone 48. Within the internal gas handling components for zone 48 are optional heating filaments that can provide catalytic cracking of the hydride (for example, NH₃). In use, the gases entering through zone 48 enter at a pressure P2.

Alkyl gases (for example, trimethyl gallium) together with N₂ (and in some instances, an optional low concentration of hydrides) enter through zone 50. In use, the gases enter through zone 50 at a pressure P1.

During typical operation, P3>P1 & P3>P2.

Central purge 52 allows for exhausting of N₂ and H₂ gases.

FIGS. 7B and 7C show instances where alkyl plus inert (for example N₂) and hydrides (for example, N₂+H₂ and NH₃) are introduced at higher concentrations, respectively.

In one example, the circular array of isolated gas injection zones is made up of four zones, each forming approximately a “pie slice” shape when viewed from a perspective where the array forms approximately a circle. A first zone may deliver mainly a hydride precursor, a second zone may deliver mainly an inert gas mixture, a third zone may deliver mainly an alkyl precursor, and a fourth zone may deliver mainly and inert gas mixture. Each slice may differ in angular extent and area so that substrates spend more or less time in each zone, as needed, thereby enabling process optimization.

Without limiting the application to processes using alkyl and hydride precursors, the invention may be more clearly described by an illustrative example. For example, a substrate passing through the four zones may pass under a first zone and come in contact with a hydride precursor, which is adsorbed on its surface as a continuous monolayer. A hot filament within the zone may be used to cause catalytic cracking of the hydride and thereby increase adsorption and/or reaction efficiency. The first zone may have a dedicated exhaust pumping port and is maintained at an approximately stable pressure P1. As the wafer carrier continues to rotate, the substrate passes under a second zone where un-adsorbed hydride gas is swept away by mainly inert gases. The second zone may have no dedicated exhaust pumping, instead allowing the mainly inert gas being injected therein to leak into adjacent zones through the low-conductance gap between the zone wall and the wafer carrier. The second zone is therefore at a higher pressure than adjacent zones, causing a pressure gradient to form across the low-conductance gap. In this way, the transport of un-adsorbed hydride precursor gas beyond the second zone may be minimized or virtually eliminated.

As rotation continues, the substrate with an adsorbed hydride precursor on its surface passes into a third zone where it comes in contact with an alkyl precursor that reacts with the adsorbed hydride precursor on its surface, thereby forming an epitaxial layer of the desired compound. The third zone may have a dedicated exhaust pumping port and is maintained at a pressure P2. As rotation of the wafer carrier continues, the substrate passes into a fourth zone where un-reacted alkyl gas is swept away by mainly inert gases. The fourth zone may have no dedicated exhaust pumping, instead allowing the mainly inert gas being injected therein to leak into adjacent zones through the low-conductance gap between the zone wall and the wafer carrier. The fourth zone is therefore at a higher pressure than adjacent zones, causing a pressure gradient to form across the low-conductance gap. In this way, the transport of un-adsorbed alkyl precursor gas beyond the second zone may be minimized or virtually eliminated. This process is repeated as the wafer carrier rotates, causing an epitaxial layer to grow upon the substrate.

In the current invention, a circular array of isolated gas injection zones may be four, eight, twelve, or any number of alternating zones in groups of four: first precursor zone, first purge zone, second precursor zone, and second purge zone. The number of zones and the rotational speed of the wafer carrier determine the deposition rate, as long as sufficient time is spent in each zone to achieve surface saturation or reaction.

The current invention has several advantages over the prior art. Its advantages over prior art MOVPE are mainly due to the elimination of precursor mixing, and its advantages over prior art ALE are mainly due to the elimination of valves and automation sequences and time limitation associated with filling and purging cycles in a single-zone process. In addition, the usage efficiency of the gases can be increased significantly (by orders of magnitude) over prior art systems since the unused/unreacted gas is not pumped out between cycles and thus has a substantially longer (by 10 times to 1000 times) residence time within each chamber. The lower gas flow rates also reduce the need for exhaust management and abatement prolonging preventative maintenance intervals. Using a dedicated exhaust for each reactant stream significantly reduces exhaust clogging by-product formation downstream of the reactor, a common problem for many ALD/ALE systems.

As used in this disclosure, the term “available energy” refers to the chemical potential of a reactant species that is used in a chemical reaction. The chemical potential is a term commonly used in thermodynamics, physics, and chemistry to describe the energy of a system (particle, molecule, vibrational or electronic states, reaction equilibrium, etc.). However, more specific substitutions for the term chemical potential may be used in various academic disciplines, including Gibbs free energy (thermodynamics) and Fermi level (solid state physics), etc. Unless otherwise specified, references to the available energy should be understood as referring to the chemical potential of the specified material.

U.S. Patent Publication No. 2007/0256635 discloses CVD reactors in which an ammonia source is activated by UV light within the reactor. These applicants also indicate that lower temperature reactions can be achieved thereby. U.S. Patent Publication No. 2006/0156983 and other such disclosures show plasma reactors using various types that high frequency power applied to the electrodes therein in order to ionize at least a portion of the reactive gas to produce at least one reactive species. It is also known that lasers can be utilized to assist in chemical vapor deposition processes. For example, in Lee et al., “Single-phase Deposition of a α-Gallium Nitride by a Laser-induced Transport Process,” J. Mater. Chem., 1993, 3(4), 347-351, laser radiation occurs parallel to the substrate surface so that the various gaseous molecules can be excited thereby. These gases can include compounds such as ammonia. In Tansley et al., “Argon Fluoride Laser Activated Deposition of Nitride Films,” Thin Solid Films, 163 (1988) 255-259, high energy photons are again used to dissociate ions from a suitable vapor source close to the substrate surface. Similarly, in Bhutyan et al., “Laser-Assisted Metalorganic Vapor-Phase Epitaxy (LMOVPE) of Indium Nitride (InN),” phys. stat. sol. (a) 194, No. 2, 501-505 (2002), ammonia decomposition is said to be enhanced at optimum growth temperatures in order to improve the electrical properties of MOVPE-grown InN films. An ArF laser is used for this purpose for photodissociation of ammonia as well as organic precursors, such as trimethylindium and the like.

Similarly, a hot electrically-resistive filament may be used to activate ammonia for enhanced reactivity with other precursors. This is analogous to hot wire CVD and catalytic CVD that has been discussed in the literature. Increasing the available energy by the use of activation technologies, such as hot filaments, UV radiation, catalysts, and other techniques familiar to those practiced in the art, are likewise envisioned for use in the current invention.

The deposition rate of the current invention is only limited by the time required for a substrate to be in any one zone for adsorption of a precursor gas layer, or reaction between two precursors, or purging of un-adsorbed or un-reacted gases. This time is estimated to be on the order of 0.1 seconds in most cases, so each compound molecular monolayer may be grown in approximately 0.4 seconds, or 1-2 nm/sec, resulting in a growth rate as high as 7 μm per hour when the wafer carrier rotates at 150 r.p.m. This growth rate is roughly on par with current MOCVD technology, and an order of magnitude faster than current ALE deposition rates. Even higher growth rates may be possible such as in cyclic or sequential CVD wherein multiple mono-layers are grown each cycle resulting in growth rates of 0.5-2 nm/cycle. Deposition uniformity is typically not as good as true ALE in which the process is self-limited to a mono-layer of growth for each exposure cycle, and planetary motion may be combined with wafer carrier rotation to improve flow and thermal uniformity across the wafer surface.

### Shaped Exhaust

One form of apparatus which has been widely employed in chemical vapor deposition includes a disc-like wafer carrier mounted within the reaction chamber for rotation about a vertical axis. The wafers are held in the carrier so that surfaces of the wafers face upwardly within the chamber. While the carrier is rotated about the axis, the reaction gases are introduced into the chamber from a flow inlet element above the carrier. The flowing gases pass downwardly toward the carrier and wafers, desirably in a laminar plug flow. As the gases approach the rotating carrier, viscous drag impels them into rotation around the axis, so that in a boundary region near the surface of the carrier, the gases flow around the axis and outwardly toward the periphery of the carrier. As the gases flow over the outer edge of the carrier, they flow downwardly toward exhaust ports disposed below the carrier. Most commonly, this process is performed with a succession of different gas compositions and, in some cases, different wafer temperatures, to deposit plural layers of semiconductor having differing compositions as required to form a desired semiconductor device.

The surface area of the wafer carrier is ideally π·R², where R is the radius of the wafer carrier. Gases flow across the wafer carrier with radial and tangential velocity components that are tailored by the design of the gas inlet arrays to provide substantially uniform process over as much of the wafer carrier as possible as it rotates. At the periphery of the wafer carrier, the gases flow around the edge and downward, toward the exhaust. This imparts a change in gas velocity, both direction and magnitude, that produces a change in partial pressure and generates a gradient across the wafer carrier, causing process non-uniformity.

Various methods have been used to address this issue in the prior art. The changes in gas partial pressure may be addressed by the addition of gas inlets, but the additional gas use lowers the efficiency of the process as much of the additional gas never comes in contact with wafers as it flows out to the exhaust. Alternately, or in combination with the addition of gas inlets, exhaust flow may be directed radially to match the flow across the wafer carrier. This latter method requires a chamber radius significantly larger than R, the radius of the wafer carrier, thus unfavorably increasing the cost of the process. An alternative to increasing the diameter of the carrier is to install a stationary (or rotating) guard ring (sometimes also known as a slip ring) around the carrier that effectively extends the edge of the carrier well beyond the substrate loading diameter. The guard ring maintains the uniformity of the boundary layer thickness to the outer boundary of the wafers and also reduces the heat loss from the carrier edge enabling a more uniform wafer temperature especially at its outer boundary on the wafer carrier. The guard ring is either directly heated (or indirectly heated by the carrier) and eventually accumulates deposition. Thus it has to be cleaned or replaced periodically to avoid process drift and auto-doping effects.

What is needed is an economical way to counter the effect of pressure change at the edge of the wafer carrier.

As illustrated in FIG. 8A, in the present invention, gas flow is compressed near the edge of the wafer carrier by modification of the chamber shape, particularly, shaping of the sidewall of the exhaust through which gas passes. The shaping compresses the gas flow upon exhaust, which compensates for the drop in pressure caused by gas flow velocity changing as it drops off the edge of the wafer carrier into the lower portion of the MOVPE chamber. This alleviates much of the edge-to-center pressure gradient, thus reducing process variations caused by variation in pressure.

Among the advantages of present invention, referred to as “shaped exhaust,” is an improvement in process uniformity across the wafer carrier, which allows the positioning of wafers closer to the edge of the wafer carrier, thus allowing potentially more wafers to be processed in a smaller space.

Another advantage of the present invention is that it allows the use of a smaller array of gas injectors, and a reduction in required gas flow. In the prior art, gas injector arrays extended radially to the edge, or even beyond the edge, of the wafer carrier. This was done to extend gas flow uniformity. Using the modified exhaust of the present invention, beneficial gas flow characteristics are extended beyond the gas injector array, so a smaller array may be utilized and less gas used to treat the wafers on the wafer carrier. For optimum deposition thickness uniformity, the total injection diameter for the alkyls, hydrides and purge (inert) gases may be different. Typically an alkyl injection diameter that extends to the edge of the wafer loading zone or is even slightly inwards from the edge of the wafer loading zone, while the purge gas extends to the edge of the injector diameter is desirable to compensate for the thinning of the boundary layer as the flow exits the wafer carrier.

As shown in FIG. 8A, gas injector system 500 has a showerhead 501 which contains gas injectors arranged to deliver processing gases to a CVD reactor. As an example, gas injector 510 introduces an inert gas, such as N2, into the reactor, gas injector 512 introduces an alkyl (such as metal organic alkyls such as trimethyl gallium, trimethyl indium, trimethyl aluminum), and gas injector 514 introduces a hydride (such as ammonia). In some instances, it may be beneficial to provide for optional heated plate/filament 508 to heat the hydride as it flows towards a wafer carrier 524 (520 showing flow of all process gases after injection) for catalytic CVD. Alkyl and hydride process gases are also injected horizontally (cross flow) through injectors (502 and 504, respectively) that are positioned in the center of the reactor. The sidewall can be adjusted as shown by arrow 526 and/or the gap between wafer carrier 524 and showerhead 510 can be adjusted (shown by arrow 528) to adjust the gap therebetween so as to optimize the reactor height, which then leads to improved gas usage and cross flow of alkyl and hydride in conjunction with the gas injection through showerhead 501 allow for uniformity tuning. FIG. 8B is sectional view of the injectors through line C of FIG. 8A. Center injection system 540 has a central gas feed tube 530 which houses separate tubing for the various process and inert gases to be injected into the system. Gases flow radially outward from central gas feed tube 530 along line 534 and 536, which can be stacked or azimuthally segmented.

### Wafer Bow Compensation and Pocket Shaping

Commonly, substrates used in manufacturing are disc shaped and referred to as “wafers.” One or more wafers rest on a structure called a wafer carrier disposed inside an MOVPE reaction chamber. The wafer carrier may rotate to average out small deviations in the MOVPE process across and within several wafers on the carrier, and to add a centrifugal pumping component over the whole to enhance laminar gas flow across the wafer surfaces. The wafer carrier acts as the thermal reservoir for the wafers, maintaining them at a uniform reaction temperature. Heat conduction between the wafers and the wafer carrier is provided by an inert gas, such as helium, that may be introduced between the carrier and each individual wafer. The fit of each wafer into individual “pockets” in the wafer carrier is critical to the uniformity of wafer temperature, and by extension, to the uniformity of the epitaxial growth process. As non-native wafers are warped during heteroepitaxial growth processing, their fit into the pockets of the wafer carrier is changed, and thus heat uniformity and the uniformity of the growth process are affected. The measurable qualities of the MQW structures therefore become non-uniform across the wafers due to variations in layer composition as an indirect consequence of the generation of internal strain from heteroepitaxy. If the wafer pocket is shaped to match wafer curvature during the most critical MQW growth part of the MOVPE process, it will not match the flat starting wafer condition or the concave wafer shape at room temperature (RT) that results from the mismatch in coefficients of thermal expansion between GaN layers and the wafer. Typical wafer bow during growth of the thick epitaxial layers is concave up due to tensile stress in the growing film. Due to this process induced wafer bow the wafer center may contact the wafer pocket in which the wafer is resting resulting in wafer tilting/displacement. In extreme cases, the wafer position may be disturbed sufficiently to dislodge the wafer from the pocket and be lost during rotation of the wafer carrier.

In some instances, the strain on the MOVPE layers being grown may transition from tension to compression, causing the wafer to first “cup,” then “bow.” For instance, the nucleation, recovery, and n-GaN layers are commonly grown under tensile strain causing concavity of the wafer, or “cupping,” while the growth of MQW layers and p-GaN is compressively strained and causes convexity of the wafer, or “bowing.” This is another factor that can lead to wafers being displaced from their pockets and lost during rotation of the wafer carrier.

What is needed is a way to compensate for wafer deformation during the MOVPE process so that at least two conditions are met: first, that the temperature uniformity of the wafer due to pocket fit is maximized during MQW layer growth, and second, that the wafer adequately fits into its pocket during all other processing stages so that it does not fall off the wafer carrier.

In the present invention, a novel approach is used to meet the requirements stated above. The conventional approach commonly employed today uses a wafer pocket bottom that is designed to match the curvature of a wafer during the MQW layer growth portion of the MOVPE process. The wafer pocket is shaped to form a surface on which all tangents are parallel to the corresponding tangent on the wafer, thus insuring an even pocket-to-wafer distance and uniform heat coupling during MQW layer growth. Though this shape may not match the shape of the wafer during nucleation, recovery, and thick n-GaN deposition, it is recessed just deeply enough to accommodate the cupped wafer without risk of wafer loss. This allows the temperature uniformity of the wafer due to pocket fit to be maximized during the critical MQW layer growth, while the wafer adequately fits into its pocket during all other processing stages so that it does not fall off the wafer carrier. Second order corrections may be made to the pocket shape to correct for systematic and repeatable temperature non-uniformity on the wafer surface such as the wafer edge, the wafer flat, wafer regions that are proximate to surrounding wafers, or in general any wafer region that experiences a different thermal environment from the majority of the wafer. This is explained in greater detail in a few paragraphs below.

FIG. 9 illustrates an alternative shaping method in the form of a flexible diaphragm that is especially well-suited to use with larger wafers. A heat conductive gas at the back of the diaphragm is maintained under regulated pressure control, so that the diaphragm may be shaped in a manner that adapts to a changing shape, for example, bowed or cupped, to match the shape of the wafer at any point during the MOVPE process. This allows a smaller gap to be maintained between the pocket and the wafer, enabling better heat transfer and uniformity. It also allows the heat uniformity to be maximized during all stages of the MOVPE growth process, not just the MQW layer growth step. Deflection of the diaphragm is monitored optically from behind or is pre-characterized as a function of, among other things, operating conditions of the chamber, pressure difference between the chamber and the cavity adjacent to the rear face of the diaphragm behind the pocket, measured deflection of the wafer and/or the diaphragm, and/or predicted process induced wafer deflection and is adjusted to match the process induced wafer deflection measured from above.

A wafer carrier 600 is provided. In some instances, the wafer carrier might be made up of several pieces (in an example, two pieces are bonded together at an interface 618). The wafer carrier 600 has one or more pockets 612 into which wafer 604 is placed. Pocket 612 can have flat bottom, can be a step pocket, or can be custom molded to address certain temperature variations. Wafer 604 is held in pocket 612 by one or more wafer supports 616 (a plan view of which is shown at 617). Where the wafer 604 has a flat edge, an appropriate quartz or sapphire cap 620 is placed within the wafer carrier 600/pocket 612. A diaphragm 610 sits between the bottom edge 624 of wafer 604 and floor surface 622 of pocket 612. Holes are cut into the diaphragm (606) and the wafer carrier (608). A conductive gas is pumped up through a spindle (not shown) onto which the wafer carrier 600 is mounted and the gas flows through opening 614 at an appropriate pressure into cavity 615, which is adjacent to the rear face of diaphragm 610, to allow for shaping of the diaphragm 610, for example, bowing or cupping, to match the shaping of wafer 604, for example, bowing or cupping, at any time during the process.

Further improvements are applied to both embodiments of the wafer bow compensation techniques described above to compensate for edge and gas flow contributions to temperature non-uniformity. Edge effects, proximity to other wafers, and gas flow may uniquely impact temperature uniformity at each wafer pocket in a wafer carrier. The thermal impacts of gas flow and wafer position in the wafer carrier make the heat loss at the front and edge of each wafer non-uniform. This is aside from and in addition to the effect of wafer bow.

The inventors have determined that the effects of edge proximity and gas flow are unique to each wafer pocket based on its location relative to other wafer pockets in a wafer carrier, and common to the same pocket in each wafer carrier. In other words, any solution that works a particular pocket in one wafer carrier will work for the corresponding wafer pocket in another. An inventive feature of one embodiment of the present invention is to modify the depth of the wafer pocket in discrete patterns to counter these effects. This non-uniformity is mapped for each wafer pocket and compensate for it at each point by adjusting the pocket-to-wafer distance, thereby altering the conduction of heat between the wafer and the pocket to balance heat loss and heat input across the wafer. This accomplished by machining various features into the floor of the pocket. This correction is structure and recipe dependent and is best implemented in a production environment where both remain fixed for a period of time. This feature is more fully described in copending U.S. Patent Published Application US 20110129947, the contents of which are hereby incorporated herein by reference.

### Fine-Tuning Wafer Temperature Using Flash Lamps and Helium Pocket Purge

Although the techniques of wafer bow compensation and pocket shaping may improve wafer heating uniformity, small differences in wafer average temperature may still exist, especially in a conventional system where a single flow of heat-conductive gas is evenly distributed to the various wafer pockets. Wafers in a single carrier may easily vary in temperature by 4-8° C. This range is essentially unchanged by turning on the heat-conductive gas, and is therefore a characteristic of the individual wafer's relationship to its pocket.

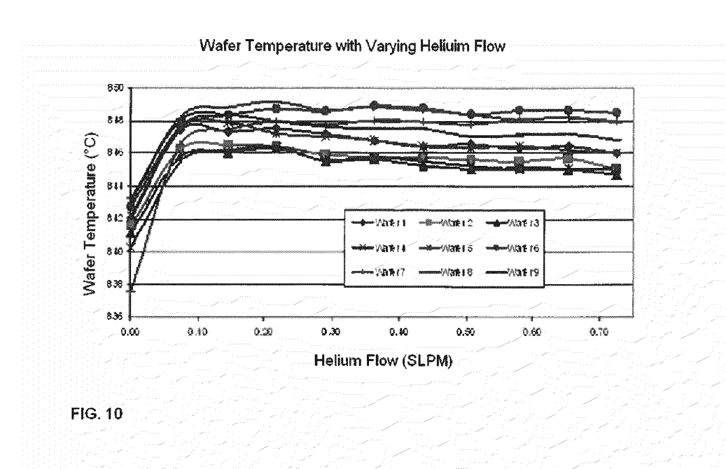

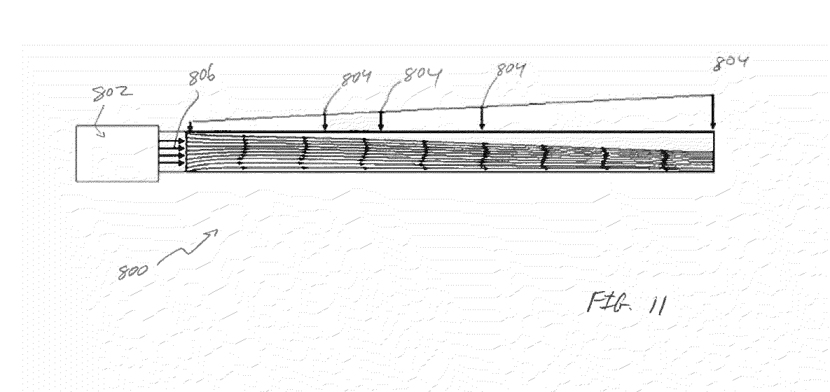

A novel feature of the present invention involves the individual control of multiple wafer temperatures within a single wafer carrier. A conductive gas, for instance helium, is individually introduced on the back side of each wafer to conduct heat between the wafer carrier and the wafer. One of the inventive features of the present invention allows heat conduction to be individually controlled at each wafer pocket on the wafer carrier by controlling the helium flow rate and thereby pressure of conductive gas flow at each pocket. As illustrated in FIG. 10, this allows adjustments to be made so that variations in the average processing temperature of individual wafers, and thus the variation in average wavelength of quantum well structures between different wafers, can be reduced.

Another inventive feature of the present invention is to direct the heat conducting gas at the back side of each wafer so it is retained by Bernoulli Effect flow and simultaneously induced to rotate within the pocket. In one embodiment of the present invention, the gas is directed to flow across the wafer's back surface while inducing rotation, so that the difference in tangential gas velocity between the back and front sides of the wafer may be used to induce a Bernoulli Effect, essentially lowering the pressure on the back side and acting to retain the wafer within the pocket, on a cushion of heat-conducting gas. This rotation, in addition to the wafer carrier rotation, generates a compound movement known as “planetary motion” that helps to improve process uniformity within each wafer. Alternate forms of planetary motion such as a gear drive accomplish a similar purpose. In some embodiments of the present invention, the planets need not rotate the wafers, provided the wafers are thermally isolated from the planetary carrier.

Complimentary to the individual backside gas heat coupling adjustments, a wafer or wafers within the wafer carrier may be individually heated by flash lamp radiation. In this embodiment, flash lamps or alternate forms of focused high repetition rate radiation such as high power blue LED lamps positioned above the wafer carrier may be triggered so that their radiation is absorbed by a selected wafer or wafers in order to add heat energy to that wafer or wafers. This may be used to supplement the foregoing gas flow adjustments, and planetary motion to correct both within wafer and wafer-to-wafer temperature non-uniformity. Alternatively, the flash lamps may be used exclusively rather than in combination with gas flow adjustment or planetary motion.

### Hybrid Wafer Carrier Heater

One of the problems encountered with high-temperature processing is the thermal “blanketing” of wafer pockets by wafers as discussed above. The difference in emissivity between a wafer and the carrier means that the temperature below a wafer will often be highest in the middle if the wafer pocket, and the wafer itself will be its highest temperature in its center. A temperature variation of 12.5° C. or more can be produced between the wafer center and its edge, a range that results in an unacceptably high variation in indium content and resulting wavelength.

One way to solve this problem is using an array of radiant heaters, disposed below the rotating wafer carrier, which may provide heat input that results in a uniformly heated wafer carrier when no wafers are present. Once the wafer carrier is loaded with wafers, radiant losses from the occupied wafer pockets are “thermally blanketed” by the wafers themselves. This induces a radial temperature non-uniformity across the wafers, characterized by a higher temperature in the wafer center.

The temperature non-uniformity is primarily localized to each wafer position, not the wafer carrier; therefore, a general wafer carrier heating solution may not be applicable. The use of individualized pocket modifications, such as the pocket shaping technique, may be effective in correcting a local temperature range of 2-5° C., but not 12.5° C. or more. In order to use fine-tuning techniques, the radial variation due to the thermal blanketing effect must be reduced.

What is needed is a way to reduce the effect of thermal blanketing at each wafer pocket to a manageable range where fine-tuning techniques can take over. This needs to be done without adding significant expense to the wafer carrier heating system.

In the present invention, a hybrid heater design, comprised of separate radiant and resistive heating elements, allows the heat input to the wafer carrier to be varied at different radial positions. By adding supplemental annular rings of resistive heaters to the wafer carrier at radii corresponding to the inner and/or outer edges of the wafer pockets, each wafer may experience additional heat input near its edge. With wafer rotation, this additional input becomes an averaged peripheral heat input that may balance the influence of thermal blanketing, resulting in a 4X reduction in temperature non-uniformity, to less than a 3° C. range. This is a range over which pocket shaping may be used to reduce the temperature variation even further. To reduce the burden on the zone heating, the surface of the carrier that is not covered by wafers may be covered by inserts that provide a similar ‘blanketing’ effect of the wafers. By eliminating sharp heat loss gradients across the carrier, the intrinsic temperature uniformity of the carrier is improved.

Thus the variation in wavelength of quantum well structures across wafers can be significantly reduced.

### Hybrid Flow Gas Injection

Vertical high-speed rotating disk reactors, in which the gas or gases are injected downwardly onto a substrate surface rotating within a reactor, are frequently employed for MOVPE. Vertical disk-type CVD reactors, in particular, have been found useful for wide varieties of epitaxial compounds, including various combinations of semiconductor single films and multilayered structures such as lasers and LEDs. In these reactors, one or more injectors spaced above a substrate carrier provide a predetermined gas flow, which upon contact with the substrate, deposits layers of epitaxial material on the surface of the substrate. The gas distribution injector system, to be effective, must be designed to compensate for precursor depletion, dilution by exhaust gases, and boundary layer changes as the gas mixture flows across the wafers.

Many existing gas injector systems have problems that may interfere with efficient operation or even deposition. For example, precursor injection patterns in existing gas distribution injector systems may contain significant “dead space” (space without active flow from gas inlets on the injector surface) resulting in recirculation patterns near the injector. Recirculation patterns have been known to result in prereaction of the precursor chemicals, causing unwanted deposition of reactants on the injector inlets (referred to herein as “reverse jetting”), resulting in lower efficiency and memory effects. Recirculation can also lead to process instability a common cause for poor run to run repeatability and chamber to chamber matching.

A gas distribution injector, such as those sold by the assignee of the present application under the trademark FlowFlange™, is mounted facing towards the wafer carrier. The injector typically includes a plurality of gas inlets that provide some combination of one or more precursor gases to the reaction chamber for MOVPE. Process-facilitating carrier gases, such as hydrogen, nitrogen, and/or inert gases, such as argon and helium, also may be introduced into the reactor through the injector. Inert gases help maintain an initial separation of reactants near the injector and laminar gas flow during the deposition process, and do not participate in VPE reactions.

The flowing gases pass downwardly toward the carrier and wafers, desirably in a laminar plug flow. As the gases approach the rotating carrier, viscous drag impels them into rotation around the axis, so that in a boundary region near the surface of the carrier, the gases flow around the axis and outwardly toward the periphery of the carrier. The injectors are typically spaced above the wafer in various positions along one or more radial axes of the wafer, relative to the central axis of the substrate carrier. Frequently, the rate of source reactant material injected into the reactor varies from injector to injector to permit the same molar quantity of reactant to reach the surface of the substrate. Hence, some reactant injectors may have different gas velocities than others. This variation in reactant velocity is, in pertinent part, due to the relative placement of the injectors. As the wafer carrier holding the substrate rotates at a predetermined rate, the injectors near the outer edge of the carrier cover a larger region of surface area on the carrier than the injectors closer to the center of the carrier in any given time period. Thus, the outer injectors typically employ a greater gas velocity of reactant than the inner injectors in order to maintain desired uniformity. For example, individual injector gas velocities may differ by a factor of as much as three to four between adjacent injectors.

While this variation in gas velocity helps to ensure a more uniform layer thickness, it may also cause turbulence between the injector flows due to their varying velocities. Also, the risk of side effects such as uneven layer thickness, dissipation of reactant, or premature condensation of reactant may be increased. The ability to tune the thickness uniformity with radial flow distribution has the drawback that the optimal settings require a trial and error approach to arrive at the optimal settings making them susceptible to human error and reactor to reactor variability. A better configuration is to use an injector that provides a uniform downward flow of gases such as has been employed in the Uniform FlowFlange. The drawback is the inability to tune the thickness uniformity locally in favor of a linearly varying thickness uniformity from carrier center to carrier edge. By adjusting the relative flows of the various gases, the thickness uniformity can be increased or decreased slightly at the outer radii of the carrier relative to the carrier center.

In another embodiment, called “cross-flow,” gases are introduced from flow inlet elements at a central hub so that laminar flow proceeds radially above and parallel to the rotating wafer carrier. As the gases cross the rotating carrier, viscous drag impels the laminar gas streams to twist, so that in a boundary region near the surface of the carrier, the twisting gas streams flow around the axis and outwardly toward the periphery of the carrier. Such cross flow designs eliminate gas flow singularities and reduce recirculation in the center of the wafer carrier, but have radially expanding boundary layers, dissipation and premature condensation of reactant, all of which limits growth rate and process uniformity.

Apparatus of both types can provide a reasonably stable and orderly flow of reactive gases over the surface of the wafer carrier and over the surface of the wafers, so that all of the wafers on the carrier, and all regions of each wafer, are exposed to relatively uniform conditions. This, in turn promotes uniform deposition of materials on the wafers. Such uniformity is important because even minor differences in the composition and thickness of the layers of material deposited on a wafer can influence the properties of the resulting devices.

In an embodiment 800 of the current invention as shown in FIG. 11, laminar gas flow from a central gas injector 802, formed from a stack of azimuthally or axially segmented injectors of Alkyl+N₂, N₂, and NH₃+N₂, travels through injector ports 806 radially across the wafer carrier as in the cross flow approach described above. In addition, however, an additional flow 804 is directed downward from above. This may be comprised of heated Nitrogen gas, or potentially, a combination of Alkyl with Nitrogen and NH₃. FIG. 11 illustrates that the downward flowing heated nitrogen gas is injected at a velocity that is linearly proportional to the distance from the central gas injector, with the desired result of compressing the boundary layer and improving process uniformity across the wafer carrier, particularly as compared with gas injection from above taken alone, as seen in FIG. 11.

In another embodiment of the current invention, a FlowFlange-type or Uniform FlowFlange-type injector is combined with a central cross-flow injector to form a hybrid injector. In this hybrid injector, the FlowFlange injector compensates for the precursor dissipation normally experienced with the cross flow injector, and the cross flow injector eliminates flow singularities and reduces recirculation at the center of the reactor, both problems inherent to FlowFlange-type injectors when used alone. The hybrid injector provides a greater ability to tune gas flow and uniformity than either the cross flow or FlowFlange alone. See also the discussion regarding FIG. 8A and FIG. 8B above.

In a yet another embodiment, the cross flow injector is positioned in an outboard peripheral relationship to the wafer carrier, so that its gas flow is directed radially inward toward a central heated exhaust port. An additional flow may be directed downward from above, comprised of heated nitrogen gas. Reactant dissipation is inherently compensated in this embodiment by geometric constriction; as the gases flow inward, they are compressed and boundary layer growth is suppressed. The exhaust port may be a vertical outlet, or it may be formed from radial ports in a central hub to avoid gas flow singularities near the center of the wafer carrier. See also the discussion regarding FIG. 6A, FIG. 6B, FIG. 6C, FIG. 6D and FIG. 16.

In still yet another embodiment of the current invention, a FlowFlange-type injector or Uniform FlowFlange-type injector is combined with a peripheral cross-flow injector to form a hybrid injector, in which gas flow is directed radially inward toward a central heated exhaust port. In this hybrid injector, the FlowFlange injector may compensate for the precursor dissipation that is not completely compensated by the geometry. The exhaust port may be a vertical outlet, or it may be formed from radial ports in a central hub to avoid gas flow singularities near the center of the wafer carrier. The hybrid injector provides a greater ability to tune gas flow and uniformity than either the cross flow or FlowFlange alone.

In all these cases, planetary motion will provide significant control and tenability of uniformity to correct for local proximity effects and achieve film thickness and film composition uniformity simultaneously especially for larger diameter substrates for which reactant depletion is a bigger concern.

### Single Wafer Reactor

As larger wafers become feasible for use in the manufacture of LEDs, single-wafer processes become more practical and advantageous. MOVPE processes have traditionally been developed to provide uniform process over wafers placed on a wafer carrier where the central portion holds no wafer and the critical processing area occupies a band between r=0 and r=R. The central portion is a region of gas stagnation, singularities, or even an axial exhaust that may cause perturbations the uniformity of the process. Such perturbations do not normally affect batch processing, since wafers may be placed outside that region, but in the case of a single wafer process this is not so.

Since a single-wafer process places one wafer over the entire wafer carrier, the single wafer reactor needs unperturbed, uniform process performance even in the center.

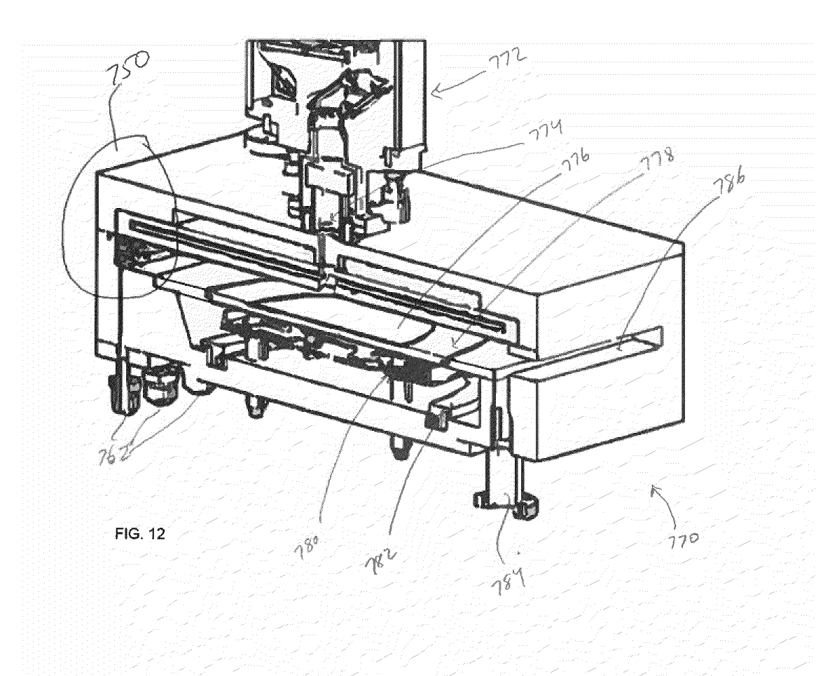

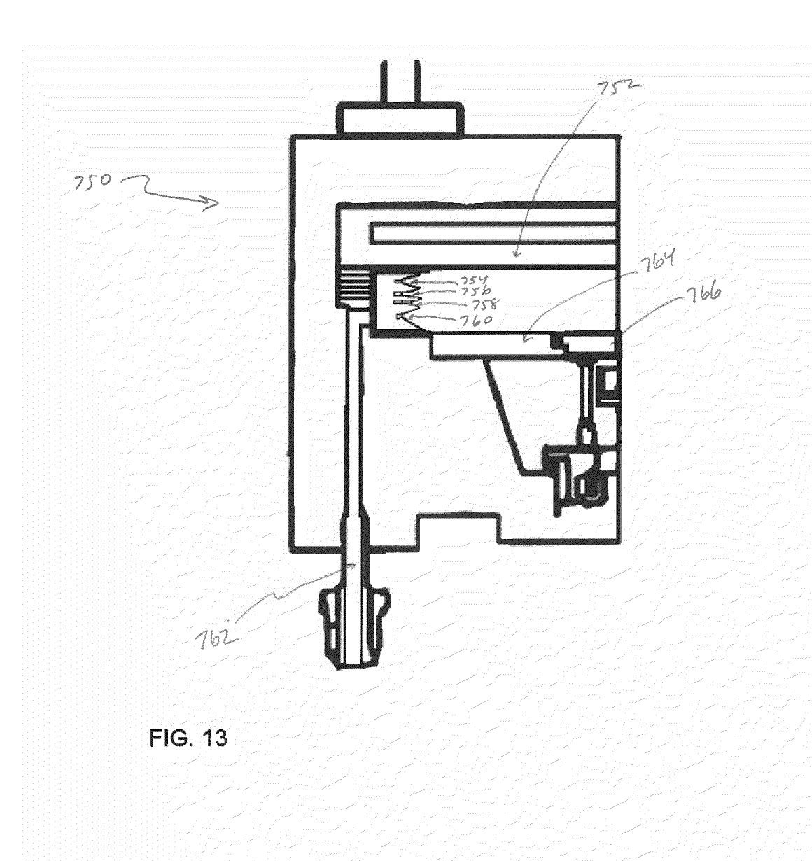

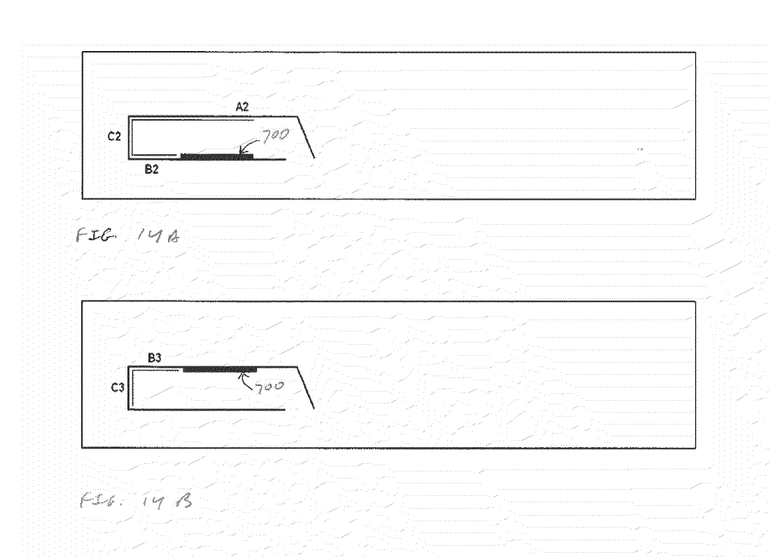

As shown in FIG. 12, in the present invention, a single-wafer MOVPE reactor provides a linearly uniform flow of gases across the rotating wafer. This is accomplished by introducing the gases through a set of linear injectors along an inner side wall within the reactor, as shown in FIG. 13. The wafer is positioned on its holder in the floor of the reactor. At the opposite side wall, a linear exhaust port provides a laminar flow exit for the flowing gases.

FIG. 12 shows system 770 as a single wafer reactor. Wafer 776 is held on wafer carrier 778, wafer carrier 778 being rotated by carrier rotation mechanism 782 (which is based on a support bearing and gas turbine system). The wafer carrier, wafer, and reactor interior are maintained at operating temperature by heater 780, which can be a single zone, radiant, infrared, RF (radio frequency) heater or a combination thereof. System 770 is also fitted with a heated vertical purge 774 and metrology tools mounted at various viewports on the reactor (for example, an in-situ pyrometer/reflectometer 772). Reactant and other gases are introduced into the reactor by system 750, described in more detail with regard to FIG. 13.

As seen in FIG. 13, system 750 provides at least four linear injectors (754, 756, 758, and 760) supplied by gas through gas port 762. Immediately adjacent to the rotating wafer (766) mounted within wafer carrier 764, a linear injector may for instance deliver a gas mixture of the precursor ammonia (NH₃) gas, hydrogen (H₂) gas, and nitrogen (N₂) gas (for example, injector 760). Another linear injector delivers the precursor metalorganic (MO) gases, N₂, and H₂ (for example, injector 756). Between these two precursor-supplying linear injectors is another linear injector that flows only N₂ purge gas to prevent adduct formation between MO and NH₃ (for example, injector 758). This linear injector, situated between the two precursor-supplying linear injectors, is also used to deliver hydrogen chloride (HCl) gas between deposition runs to clean the reactor.

The top plate, or reactor ceiling 752, is positioned opposite to the wafer 766 within the reactor. A fourth linear injector 754, immediately adjacent to the top plate or ceiling of the reactor, provides a flow of N₂ gas that forms a protective sheath flow between the flow of reactive gases below and the reactor ceiling. This protective flow acts to reduce the formation of parasitic deposition on the reactor ceiling.

The ceiling may be additionally protected from parasitic deposition by an injector array integrated into its structure that provides heated N₂ gas flow. This gas flow combines with the N₂ flow from the linear array when both are used, providing additional protection for the ceiling or top plate from parasitic depositions.

An alternative embodiment of the present invention is where the wafer is inverted and facing downward into the reactor. The advantage of this embodiment is that the wafer is no longer situated below a surface, such as a ceiling, that may accumulate a parasitic deposition, as it is in the first described embodiment. The floor of the reactor may be allowed to accumulate parasitic depositions that are periodically cleaned off between processes by HCl flow. Any participation (i.e.; spalling or flaking) of parasitic depositions on the reactor floor during process are swept from the reactor by the linear laminar flow of process gases, and do not make contact with the wafer above. This embodiment may allow for simplification of the reactor by eliminating the need for heated N₂ purge through and along the surface (i.e.; the floor) opposite the wafer. The wafer can be heated, for example, by placing heating elements or heat lamps between the ceiling of the reactor and the wafer underside (the surface of the wafer that is facing the reactor ceiling) or placing heating elements or heat lamps between the floor of the reactor and the wafer surface on which structures are to be grown.

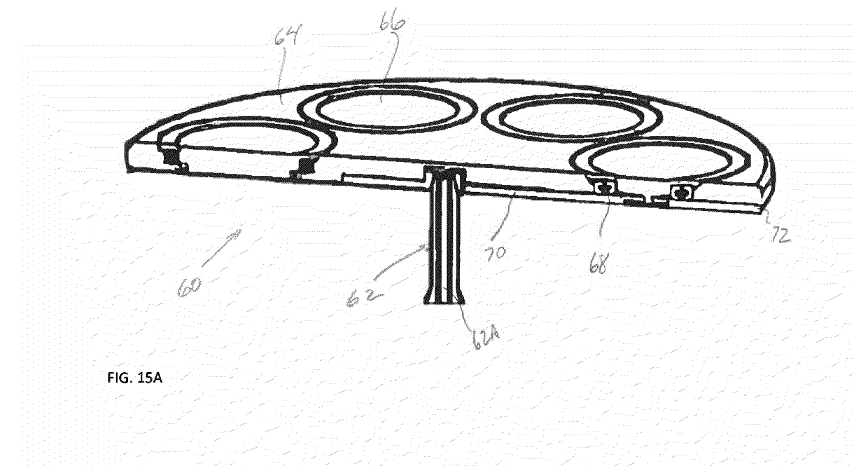

FIG. 14A illustrates the aspects of anoninverted reactor that reduce parasitic deposition on a wafer 700. Purge flow and plasma cleaning are used along the ceiling A2 and floor B2. Furthermore, the injector is designed so as to avoid deposition along the floor B2 and to prevent recirculation to avoid deposition at the injector site C2.

FIG. 14B illustrates the use of nonrecirculating injector design in the injector site C3 and plasma cleaning and purge flow along ceiling B3 to avoid parasitic deposition on wafer 700 in the inverted configuration.

In either embodiment, the precursor-supplying linear injectors may be further enhanced by segmentation. For example, the linear injector that delivers MO, N₂, and H₂ may be comprised of three or more segments with each segment delivering a different ratio of the three gases. The ratio of gases delivered through each segment may be tuned to optimize the uniformity of growth on the wafer and/or minimize the growth of parasitic depositions in other areas.

on-Board PL Mapping and Model-Based Process Control

In production, MOVPE reactors are required to process continuously. After extended use, the reactor's processes may begin to drift. Process drift may cause within wafer and wafer-to-wafer non-uniformity of the grown layers, and consequent yield loss. One useful tool for detecting process drift during MOVPE for LEDs is photoluminescence (PL). The PL response of a wafer can be mapped after multi-quantum well growth to detect process drift resulting in variations in the indium incorporation and thickness.

In the present invention, PL mapping in incorporated into the MOVPE system, and any drift detected is correlated to known factors and responses. For instance, a uniform change in the PL over all wafers in an entire wafer carrier may indicate a drift toward higher or lower processing temperature. If the process has been thoroughly modeled, the cause of the drift may be accurately attributed to one or two factors. Small adjustments to the suspected factors are automatically “fed forward” to detect a corrective response, as measured on the next wafers to be processed. Thus, the MOVPE system may continue to process wafers within process specifications, and extend the mean time between periodic maintenance cycles. This can have a significant impact on the cost per yielded die. Analogously other in-situ or on-board metrology may be included that can be used within a process control loop either for run to run control or for excursion and fault detection. Examples include sensors to measure film thickness, resistivity/doping, electrical characteristics at a wafer level and surface defects such as particles, cracks, slip, epi growth defects. Many of these are best performed in a controlled ambient with the substrates at a well defined temperature and hence are most amenable to on-board implementation where the sensor is located outside the growth chamber but internal to the overall system.

### Heated FlowFlange and Fast GaN

The present invention contemplates a heated inlet, in which the gases are at an inlet temperature above about 75° C., and such as above about 100° C. and about 100° C. to about 250° C. when introduced into the chamber. Preferably, the walls of the chamber are maintained at a temperature within about 50° C. of the inlet temperature.

This aspect of the invention can provide significant improvements in operating range. In particular, the preferred methods according to this aspect of the invention can operate at lower rotational speeds, lower gas flow rates, and higher pressures than similar processes using lower gas inlet temperatures. Increases in gas inlet temperature increases buoyancy forces and increases the stable process window, thus permitting higher pressures or lower rotation rates, and increasing hydride usage efficiency. Further, hotter inlet gas provides less surface cooling, leading to greater temperature stability and reduction of adduct formation. It has been found that there is a greater than 35% increase in alkyl efficiency when changing the inlet flange temperature from 50 to 200° C. There has also been found a significant (greater than 85%) reduction in the use of NH₃, N₂ and H₂ by the same change in inlet flange temperature. These features, as well as others, are more fully described in copending U.S. Patent Published Application 20100112216, the contents of which are hereby incorporated herein by reference and in copending U.S. patent application Ser. No. 13/128,163, filed Jun. 17, 2011 (and which is related to U.S. Patent Published Application 20100112216), the contents of which are hereby incorporated herein by reference.

A further aspect of the present invention provides a chemical vapor deposition reactor. The reactor according to this aspect of the invention desirably is a rotating-disc reactor, and desirably includes a flow inlet temperature control mechanism arranged to maintain the flow inlet element of the reactor at an inlet temperature as discussed above in connection with the method. Most preferably, the reactor also includes a chamber temperature control mechanism arranged to maintain the walls of the chamber at a wall temperature as discussed above.

The wafer temperature normally is set to optimize the desired deposition reaction; it is commonly above 400° C. and most typically about 700-1100° C. It is generally desirable to operate equipment of this type at the highest chamber pressure, lowest rotation speed and lowest gas flow rate which can provide acceptable conditions. Pressures on the order of 10 to 1000 Torr, and most commonly about 100 to about 750 Torr, are commonly used. Lower flow rates are desirable to minimize waste of the expensive, high-purity reactants and also minimize the need for waste gas treatment. Lower rotation speeds minimize effects such as centrifugal forces and vibration on the wafers. Moreover, there is normally a direct relationship between rotation speed and flow rate; under given pressure and wafer temperature conditions, the flow rate required to maintain stable, orderly flow and uniform reaction conditions increases with rotation rate.

Prior to the present invention, however, the operating conditions which could be used were significantly constrained. It would be desirable to permit lower rotation speeds and gas flows, higher operating pressures, or both, while still preserving the stable flow pattern.

Fast GaN MOVPE processing is a process embodiment of the current invention. The precursor gases used for GaN growth in the prior art are introduced through the injection system at a temperature of around 50° C. In the Fast GaN process, gases are injected at a temperature of about 200° C.

The higher temperature of the precursor gases improves surface mobility and reaction kinetics, leading to a higher growth rate of about 8-15 μm per hour compared to 2-5 μm per hour for prior art processing.

Because the gases are hotter and so absorb less heat from the substrates, the wafer temperature uniformity, and subsequent GaN thickness and indium incorporation uniformity are improved in the current inventive embodiment.

The increase in surface mobility and reaction kinetics caused by introducing the precursors at 200° C. allows lower gas flow rates to be used, resulting in better material utilization and reduced cost. It also allows the rotation speed of the wafer carrier to be reduced from a typical 1200 r.p.m. to less than 600 r.p.m., thereby extending the useful life of bearings and reducing heat loss and power requirements. The gas consumption for N₂, H₂ and NH₃ drops by 5×-8× for growing a defined GaN thickness compared to conventional growth conditions, all of which translate to a significant reduction if epitaxial growth cost.

### Inertial Drive Planetary Rotation Mechanism

In order to provide a uniform process across a substrate, practitioners have historically relied on various substrate motions. Most commonly, linear scanning and rotation have been used. In the case of deposition and etch processing, a compound motion involving individual rotation about the substrate center is coupled with angular rotation about a secondary axis, usually at the center of a multi-wafer carrier. The individual wafer holders in this case are referred to as “planets,” that may rotate within their positions in the wafer carrier.

To drive rotation within the individual planets, which are allowed to rotate within their positions in the wafer carrier, gear teeth or other direct coupling is provided between the individual wafer holders and a either a stationary central hub or a fixed peripheral ring. When the multi-wafer carrier is driven to rotate, the planets are rolled around the fixed hub or ring and thus caused rotate individually.

The circumference of the planet relative to the hub or ring uniquely determines the relative motion of the planet within the wafer carrier. For planets driven by a fixed hub, rotation will be in the same sense as wafer carrier rotation, i.e., the planets will rotate clockwise when the wafer carrier rotates clockwise. The exact opposite holds for planets driven by a fixed ring.

It may be advantageous in any process to provide, during processing, a change in the relative speed or rotational sense of the planetary motion. There exists no mechanism in the prior art to allow this, and therefore the current invention provides a potentially valuable capability. In addition, controlling the planetary rotational speed to a relatively low value such as below 30 rpm even if the carrier is rotating at 600 rpm or higher is desirable to avoid flow instabilities created by high speed carrier rotation, which would overwhelm the main flow pattern generated by wafer carrier rotation.

The present invention uniquely enables a wide range of compound substrate motion during MOVPE or any other type of wafer process, including CVD, PVD, or ion beam processes.

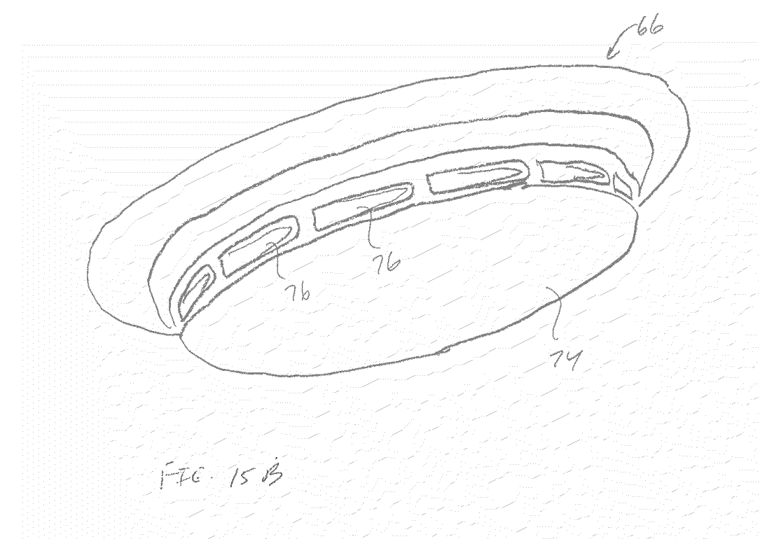

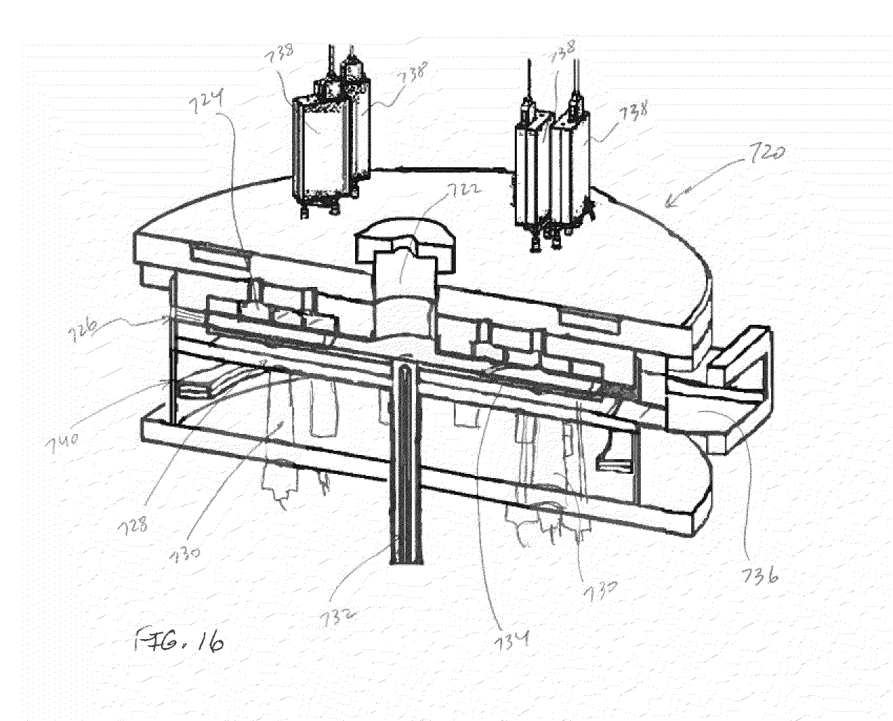

As seen in FIG. 15A, and in perspective view in FIG. 15B, a wafer carrier of the present invention has situated upon it one or more eccentrically positioned planets made from silicon carbide (SiC) or graphite coated with SiC, each supported on SiC or silicon nitride (SiN) bearings within its own individual recessed nest on the wafer carrier. There are gear teeth or other coupling means around each wafer holder.

In FIG. 15A, planetary motion system 60 shows a planetary wafer carrier 64 mounted on spindle 62. Spindle 62 contains gas flow system 62A which delivers an inert gas, for example, Helium, into gas groove 70 which then delivers the inert gas to various turbine vanes 76 (as shown in FIG. 15B) found at the bottom sides of wafer holder 66. Wafer holder 66 is seated within wafer carrier 64 on bearings (for example, ceramic bearings) 68. There can be a small gap between the bottom of wafer holder 66 (bottom 74 in FIG. 15B) and inner bottom of wafer carrier 66 (not shown). When the inert gas (for example Helium) impinges upon the turbine vanes 76, the wafer holder 66 will then rotate on bearings 68. The speed of rotation and the temperature of the wafer holder 66 can be controlled by varying the temperature and gas flow rate of the gas entering through system 62A.

The wafer carrier, in the form a disc, is centrally supported on a rotatable spindle and hub assembly. Direct contact between the wafer carrier and the hub is through a supporting ring of SiC or SiN bearings, so the wafer carrier is able to rotate independently of the hub. The hub has gear teeth around its perimeter that project into openings on the wafer carrier where the individual planets are retained, so that they mesh with the gear teeth on the periphery of each planet.

In the present invention, the central hub is part of the drive assembly, and so is not fixed, but may be driven to rotate at any speed and in either directional sense, clockwise or counterclockwise. When the hub rotates, the gear mesh coupling to the planets causes the planets to individually rotate within their positions in the same rotational sense and at a speed initially proportional to the ratios of the circumferences of the hub and planets.

The coupling between the hub and the wafer carrier is through the rolling friction transferred across the bearings. Thus, the wafer carrier's rotational acceleration is lower than that of the hub. As the wafer carrier begins to rotate, the ratio of the rotational speed of the planets to the hub changes and the wafer holders necessarily rotate more slowly relative to the hub. When the hub ceases its rotational acceleration and turns at a constant rotational velocity, the wafer carrier continues to accelerate until it reaches a rotational velocity at which all forces on it are balanced, i.e., when the friction across the bearings is balanced by drag from the gases present.

The continuation of wafer carrier rotational acceleration, after the hub has reached a constant velocity, causes the relative rotational velocity of the planets to decrease. Once the wafer carrier reaches the rotational speed of the hub, the planets cease to rotate individually.

By periodically accelerating and decelerating the hub about a constant average speed, the planets are induced to periodically reverse their direction of rotation while the wafer carrier continues to rotate with the same average velocity (in the same directional sense). This complex motion is notably different from motions achieved in the prior art, and provides a unique method of averaging and evening process performance across individual wafers. This feature is more fully described in copending U.S. Patent Application Serial No. US20110300297, the contents of which are hereby incorporated herein by reference.

### Combinations

Combinations of the various inventions described herein are potentially advantageous and form further embodiments of the disclosed inventions. For example, FIG. 16 illustrates a chamber combining a heated central exhaust, peripheral injectors with three zones, providing controlled premixing of reactants, pre-heating and radially inward flow, multi-zone heating, a multi zone showerhead for spatially distributed reactant injection patterned to reduce boundary layer thickness and minimize ceiling deposition, planetary motion with inertial variation, multi-point pyrometry including a reflectometer and deflectometer, and automated loading, in-situ cleaning and four chambers arranged in a cluster tool.

In FIG. 16, system 720 has a heated central exhaust 722 from where process gases entering the reactor 740 from multi-zone showerhead 724 and a three zone peripheral injector 726. Multi-zone showerhead 724 provides for spatially distributed reactant injection. Three zone peripheral injector 726 allows for controlled pre-mixing of reactants and pre-heating of hydrides (for example, NH₃) and inert gases. The combination of the multi-zone showerhead 724 and the three zone injector 726 reduce boundary layer thickness on coated wafers and minimizes deposition on the ceiling of reactor 740. Wafer carrier 734 can be a traditional wafer carrier or a planetary motion type carrier and sits within reactor 740 on spindle 732. The carrier and wafers situated thereon are kept at operating temperature by a multi-zone heater 728 and lamps 730. Metrology units 738, for example, multi-point pyrometer, reflectometer, and/or deflectometer, can be used to not only monitor the wafer temperature but also can be used to provide feedback to other reactors that can be connected to system 720 in a cluster or other tool arrangement.

It is the intent of the inventors to include each embodiment in any practical combination with any other embodiments herein disclosed, whether obvious or not to those practiced in the art. For example, in one embodiment of the present invention, a heated flow flange showerhead and a shaped exhaust flow are combined to substantially reduced variation in the boundary layer thickness over an entire multi-substrate platen during film growth, thereby reducing variations in process typically caused by changes in boundary layer thickness.

While the present invention has been illustrated by a description of various embodiments and while these embodiments have been described in considerable detail, it is not the intention of the applicants to restrict or in any way limit the scope of the appended claims to such detail. Additional advantages and modifications will readily appear to those skilled in the art. The invention in its broader aspects is therefore not limited to the specific details, representative apparatus and method, and illustrative example shown and described. Accordingly, departures may be made from such details without departing from the spirit or scope of applicant's general inventive concept.

What is claimed is:

1. A vapor phase epitaxy reactor comprising:
a. a chamber having walls;
b. a wafer carrier within the chamber; and
c. a plurality of gas flow injectors located at a plurality of injection sites respectively configured to produce a process gas flow for the epitaxy process; and
d. a combining gas flow system to adapt the profile of gas flow across a surface of a wafer within the chamber.

2. The reactor of claim 1 wherein the combining gas flow system comprises a first gas flow injector injecting processing gas from a central gas injector axially across the surface of the wafer towards the walls of the chamber and a second gas flow injector injecting heated gas to mix with the processing gas, the second gas injector injecting gas downwardly toward the surface of the wafer at a velocity related to the distance from the central gas injector.

3. The reactor of claim 2 wherein the second gas flow injector injects heated gas at a velocity proportional to the distance from the central gas injector.

4. The reactor of claim 1 further comprising a central heated exhaust port, wherein a first gas flow injector injects processing gas and a second gas flow injector injects heated gas to mix with the processing gas, the second gas flow injector positioned in an outboard peripheral relationship to the wafer and configured to generate gas flow directed radially inward toward the exhaust port.

5. The reactor of claim 4 wherein a third gas flow injector directs additional gas flow downward from above.

6. The reactor of claim 1 wherein a first gas flow injector injects processing gas and a second gas flow injector injects heated gas to mix with the processing gas, the second gas injector injecting gas along an inner side wall within the reactor.
